(19) United States
(12) Patent Application Publication
(10) Pub. No.: US 2023/0234613 A1
(43) Pub. Date: Jul. 27, 2023

(54) TESTING AND SIMULATION IN AUTONOMOUS DRIVING

(71) Applicant: FIVE AI LIMITED, Bristol (GB)

(72) Inventors: Iain Whiteside, Edinburgh (GB); John Redford, Cambridge (GB)

(73) Assignee: FIVE AI LIMITED, Bristol (GB)

(21) Appl. No.: 18/008,070

(22) PCT Filed: Jun. 3, 2021
(86) PCT No.: PCT/EP2021/064938

§ 371 Date: Dec. 2, 2022

(30) Foreign Application Priority Data
Jun. 3, 2020 (GB) 2008354.9
Sep. 4, 2020 (EP) 20194498.0
Apr. 23, 2021 (GB) 2105836.7
Jun. 2, 2021 (GB) 2107876.1

(51) Int. Cl. B60W 60/00; B60W 50/04; G06F 30/20

(52) U.S. Cl. CPC B60W 60/0011; B60W 50/045; G06F 30/20; B60W 2050/046; B60W 2554/80

(57) ABSTRACT

A computer-implemented method of evaluating the performance of a full or partial autonomous vehicle (AV) stack in simulation, the method comprising: applying an optimization algorithm to a numerical performance function defined over a scenario space, wherein the numerical performance function quantifies the extent of success or failure of the AV stack as a numerical score, and the optimization algorithm searches the scenario space for a driving scenario in which the extent of failure of the AV stack is substantially maximized, wherein the optimization algorithm evaluates multiple driving scenarios in the search space over multiple iterations, by running a simulation of each driving scenario in a simulator, in order to provide perception inputs to the AV stack, and thereby generate at least one simulated agent trace and a simulated ego trace reflecting autonomous decisions taken in the AV stack in response to the simulated perception inputs, wherein later iterations of the multiple iterations are guided by the results of previous iterations of the multiple iterations, with the objective of finding the driving scenario for which the extent of failure of the AV stack is maximized.

### TECHNICAL FIELD

The present disclosure relates to the testing of autonomous vehicle stacks through simulation.

### BACKGROUND

There have been major and rapid developments in the field of autonomous vehicles. An autonomous vehicle is a vehicle which is equipped with sensors and control systems which enable it to operate without a human controlling its behaviour. An autonomous vehicle is equipped with sensors which enable it to perceive its physical environment, such sensors including for example cameras, radar and lidar. Autonomous vehicles are equipped with suitably programmed computers which are capable of processing data received from the sensors and making safe and predictable decisions based on the context which has been perceived by the sensors. There are different facets to testing the behaviour of the sensors and control systems aboard a particular autonomous vehicle, or a type of autonomous vehicle.

Sensor processing may be evaluated in real-world physical facilities. Similarly, the control systems for autonomous vehicles may be tested in the physical world, for example by repeatedly driving known test routes, or by driving routes with a human on-board to manage unpredictable or unknown contexts.

Physical world testing will remain an important factor in the testing of autonomous vehicles capability to make safe and predictable decisions. However, physical world testing is expensive and time-consuming. Increasingly there is more reliance placed on testing using simulated environments. Autonomous vehicles need to have the facility to operate in the same wide variety of circumstances that a human driver can operate in. Such circumstances can incorporate a high level of unpredictability.

It is not viable to achieve from physical testing a test of the behaviour of an autonomous vehicle in all possible scenarios that it may encounter in its driving life. Increasing attention is being placed on the creation of simulation environments which can provide such testing in a manner that gives confidence that the test outcomes represent potential real behaviour of an autonomous vehicle.

Simulation environments need to be able to represent real-world factors that may change in the road layout in which it is navigating. This can include weather conditions, road types, road structures, junction types etc. This list is not exhaustive, as there are many factors that may affect the operation of an ego vehicle. A complex AV stack can be highly sensitive to small changes in road layout, environmental conditions, or a particular combination of factors might result in failure in a way that is very hard to predict.

One approach to simulation testing is “scenario fuzzing”. For example, a real-world scenario may be recorded in some form that allows it to be re-created in a simulator, but in a configurable manner. The scenario might be chosen on the basis that it led to failure of an AV in the real world (requiring test driver intervention in the real world). Scenario fuzzing is typically based on randomized or manual changes to parameters of the scenario, with the aim of understanding the cause of the failure.

### SUMMARY

A core problem addressed herein is that, as AV stacks improve, the percentage of failure cases decreases. One estimation is that, in order to match human drivers in terms of safety, an AV stack should be capable of making and implementing decisions with an error rate no greater than 1 in 10⁷. Verifying performance at this level in simulation requires the stack to be tested in numerous simulated driving scenarios.

The present techniques increase the efficiency with which the most “challenging” driving scenarios can be located and explored. The problem of finding the most challenging scenarios is formulated as an optimization problem where the aim is to find driving scenarios on which an AV stack under testing is most susceptible to failure. To do so, success and failure is quantified numerically (as one or more numerical performance scores), in a way that permits a structured search of a driving scenario space. The aim is to find scenarios that lead to the worst performance scores, i.e. the greatest extent of failure.

A first aspect herein provides a computer-implemented method of evaluating the performance of a full or partial autonomous vehicle (AV) stack in simulation, the method comprising:
applying an optimization algorithm to a numerical performance function defined over a scenario space, wherein the numerical performance function quantifies the extent of success or failure of the AV stack as a numerical score, and the optimization algorithm searches the scenario space for a driving scenario in which the extent of failure of the AV stack, as indicated by the numerical score, is substantially maximized;
wherein the optimization algorithm evaluates multiple driving scenarios in the search space over multiple iterations, by running a simulation of each driving scenario in a simulator, in order to provide perception inputs to the AV stack, and thereby generate at least one simulated agent trace and a simulated ego trace reflecting autonomous decisions taken in the AV stack in response to the simulated perception inputs, wherein later iterations of the multiple iterations are guided by the results of previous iterations of the multiple iterations, with the objective of finding the driving scenario for which the extent of failure is maximized.

Embodiments recognize that not every instance of failure is necessarily that informative. For example, if a stack is tested in simulation, a failure of a stack on an unrealistic or highly unlikely scenario is generally less informative than a failure on a more realistic or likely scenario. Failure on a scenario that could not reasonably have been passed (e.g. by a competent human driver) are also less informative.

In embodiments, the later iterations may be guided by the earlier iterations, in combination with a predetermined acceptable failure model, with the objective of finding a driving scenario for which (i) the extent of failure is maximized and (ii) failure is unacceptable according to the acceptable failure model, whereby any driving scenario having (iii) a greater extent of failure but (iv) on which failure is acceptable according to the acceptable failure model is excluded from the search.

The acceptable failure model may be applied to the simulated ego trace and the simulated agent trace of at least generated in at least one of the driving scenarios, in order to determine whether failure on that driving scenario is acceptable or unacceptable.

The scenario space may be defined by one or more scenario parameters.

In the case that the scenario space is defined by one or more scenario parameters, the acceptable failure model may exclude, from the search, predetermined values or combinations of values of the scenario parameter(s).

Each driving scenario may be defined by a particular parameterization (particular value(s) of the scenario parameter(s)). The scenario parameter(s) may be parameters of a scenario description, and each driving scenario may be an instance of the scenario description.

In either of the above cases, a constrained optimization method may be used with the objective of finding a driving scenario fulfilling (i) and (ii) above. In this context, (ii) may be formulated as a set of hard and/or soft constraint(s) on the constrained optimization of (i).

The acceptable failure model may comprise one or more statistics (such as a number or frequency of certain events or actors) derived from real-world driving data, which are compared with corresponding statistic(s) of a driving scenario, in order to determine whether or not failure on that driving scenario is acceptable.

The acceptable failure model may comprise one or more acceptable failure rules applied to one or more blame assessment parameters extracted from the simulated traces.

In embodiments, the optimization algorithm may be gradient-based, wherein each iteration computes a gradient of the performance function and the later iterations are guided by the gradients computed in the earlier iterations.

When formulated as a constrained optimization problem, a constrained gradient-based method (such as projected gradient descent) may be used.

The gradient of the performance function may be estimated numerically in each iteration.

Each scenario in the scenario space may be defined by a set of scenario description parameters to be inputted to the simulator, the simulated ego trace dependent on the scenario description parameters and the autonomous decisions taken in the AV stack.

The performance function may be an aggregation of multiple time-dependent numerical performance metrics used to evaluate the performance of the AV stack, the time-dependent numerical performance metrics selected in dependence on environmental information encoded in the description parameters or generated in the simulator.

The numerical performance function is defined over a continuous numerical range.

The numerical performance function may be a discontinuous function over the whole of scenario space, but locally continuous over localized regions of the scenario space, wherein the method comprises checking that each of the multiple scenarios is within a common one of the localized regions.

The numerical performance function may be based on at least one of:
distance between an ego agent and another agent,
distance between an ego agent and an environmental element,
comfort assessed in terms of acceleration along the ego trace, or a first or higher order time derivative of acceleration,
progress.

Further aspects herein provide a computer system comprising one or more computers programmed or otherwise configured to implement any of the method steps, and a computer program comprising program instructions for programming a computer system to carry out the method steps.

### BRIEF DESCRIPTION OF FIGURES

For a better understanding of the subject matter taught herein, and to show how embodiments of the same may be carried into effect, reference is made to the following figures in which:

FIG. 1A shows a schematic function block diagram of an autonomous vehicle stack;

FIG. 1B shows a schematic overview of an autonomous vehicle testing paradigm;

FIG. 2 shows a schematic block diagram of a testing pipeline;

FIG. 2A shows further details of a possible implementation of the testing pipeline;

FIG. 3 shows further details of the testing pipeline;

FIG. 3A shows an example of a rule tree evaluated within a test oracle;

FIG. 3B shows an example output of a node of a rule tree;

FIG. 4 illustrates how the effect of changes to a set of scenario parameters can be quantified in terms of numerical performance metrics in the context of AV testing;

FIG. 4A shows an example of a rule tree to be evaluated within a test oracle;

FIG. 4B shows a second example of a rule tree evaluated on a set of scenario ground truth data;

FIG. 4C shows how rules may be selectively applied within a test oracle;

FIG. 5 shows a schematic block diagram of a visualization component for rendering a graphical user interface;

FIGS. 5A, 5B and 5C show different views available within a graphical user interface; and

FIG. 6 illustrates one example of an optimization performed over a scenario space, with the objective of finding driving scenarios on which a tested Av stack exhibits the worst quantified performance.

FIG. 6A shows a first instance of a cut-in scenario;

FIG. 6B shows an example oracle output for the first scenario instance;

FIG. 6C shows a second instance of a cut-in scenario;

FIG. 6D shows an example oracle output for the second scenario instance;

FIG. 7 shows a block diagram of an extended test oracle capable of receiving and applying an acceptable failure model;

FIG. 8 shows a flow chart for a blame assessment method;

FIG. 9 shows an extended graphical user interface rendered in a computer system; and

FIG. 10 shows a schematic block diagram of a scenario extraction pipeline.

### DETAILED DESCRIPTION

There is described below a testing pipeline that can be used to test the performance of all or part of an autonomous vehicle (AV) runtime stack. The testing pipeline is highly flexible and can accommodate many forms of AV stack, operating at any level of autonomy. Note, the term autonomous herein encompasses any level of full or partial autonomy, from Level 1 (driver assistance) to Level 5 (complete autonomy).

A typical AV stack includes perception, prediction, planning and control (sub)systems. The term “planning” is used herein to refer to autonomous decision-making capability (such as trajectory planning) whilst “control” is used refer to the generation of control signals for carrying out autonomous decision. The extent to which planning and control are integrated or separable can vary significantly between different stack implementations - in some stacks, these may be so tightly coupled as to be indistinguishable (e.g. such stacks could plan in terms of control signals directly), whereas other stacks may be architected in a way that draws a clear distinction between the two (e.g. with planning in terms of trajectories, and with separate control optimizations to determine how best to execute a planned trajectory at the control signal level). Unless otherwise indicated, the planning and control terminology used herein does not imply any particular coupling or separation of those aspects.

However a stack is “sliced” for the purpose of testing, the idea of simulation-based testing for autonomous vehicles is to run a simulated driving scenario that an ego agent must navigate, often within a static drivable area (e.g. a particular static road layout) but typically in the presence of one or more other dynamic agents such as other vehicles, bicycles, pedestrians, animals etc. (also referred to as actors or external agents). Simulated perception inputs are derived from the simulation, which in turn feed into the stack or sub-stack under testing, where they are processed in exactly the same way as corresponding physical perception inputs would be, so as to drive autonomous decision making within the (sub-)stack. The ego agent is, in turn, caused to carry out those decisions, thereby simulating the behaviours or a physical autonomous vehicle in those circumstances. The simulated perception inputs changes as the scenario progresses, which in turn drives the autonomous decision making within the (sub-) stack being tested. The results can be logged and analysed in relation to safety and/or other performance criteria. Note the term perception input as used herein can encompass “raw” or minimally-processed sensor data (i.e. the inputs to the lowest-level perception components) as well as higher-level outputs (final or intermediate) of the perception system that serve as inputs to other component(s) of the stack (e.g. other perception components and/or prediction/planning).

Slicing refers to the set or subset of stack components subject to testing. This, in turn, dictates the form of simulated perception inputs that need to be provided to the (sub-)stack, and the way in which autonomous decisions.

For example, testing of a full AV stack, including perception, would typically involve the generation of sufficiently realistic simulated sensor inputs (such as photorealistic image data and/or equally realistic simulated lidar/radar data etc.) that, in turn, can be fed to the perception subsystem and processed in exactly the same way as real sensor data. The resulting outputs of the perception system would, in turn, feed the higher-level prediction and planning system, testing the response of those components to the simulated sensor inputs. In place of the physical actor system, an ego vehicle dynamics model could then be used to translate the resulting control signals into realistic motion of an “ego agent” within the simulation, thereby simulating the response of an ego vehicle to the control signal.

By contrast, so-called “planning-level” simulation would essentially bypass the prediction system. A simulator would provide simpler, higher-level simulated perception inputs that can be fed directly to the prediction and planning components, i.e. rather than attempting to simulate the sensor inputs to the perception system, the simulator would instead simulate the outputs of the perception system which are then inputted to the prediction/planning systems directly. As a general rule, the “lower down” the stack is sliced, the more complex the required simulated perception inputs (ranging from full sensor modelling at one extreme to simple simulated fused location/orientation measurements etc. at the other, which can be derived straightforwardly using efficient techniques like ray tracing).

Between those two extremes, there is scope for many different levels of input slicing, e.g. testing only a subset of the perception system, such as “later” perception components, i.e., components such as filters or fusion components which operate on the outputs from lower-level perception components (such as object detectors, bounding box detectors, motion detectors etc.).

In any of the above, for stacks where control is separable from planning, control could also be bypassed (output slicing). For example, if a manoeuvre planner of the stack plans in terms of trajectories that would feed into a control system within the full stack, for the purpose of the simulation, it could simply be assumed that the ego agent follows each planned trajectory exactly, which bypasses the control system and removes the need for more in-depth vehicle dynamics modelling. This may be sufficient for testing certain planning decisions.

In the following examples, the performance of the stack is assessed, at least in part, by evaluating the behaviour of the ego agent in the test oracle against a given set of performance evaluation metrics, over the course of one or more runs. The metrics are applied to “ground truth” of the (or each) scenario run which, in general, simply means an appropriate representation of the scenario run (including the behaviour of the ego agent) that is taken as authoritative for the purpose of testing. Ground truth is inherent to simulation; a simulator computes a sequence of scenario states, which is, by definition, a perfect, authoritative representation of the simulated scenario run. In a real-world scenario run, a “perfect” representation of the scenario run does not exist in the same sense; nevertheless, suitably informative ground truth can be obtained in numerous ways, e.g. based on manual annotation of on-board sensor data, automated/semi-automated annotation of such data (e.g. using offline/non-real time processing), and/or using external information sources (such as external sensors, maps etc.) etc.

The testing pipeline is described in further detail below but first an example AV stack is described in further detail. This solely to provide context to the description of the testing pipeline that follows. As noted, the described testing pipeline is flexible enough to be applied to any AV stack or sub-stack, within any desired testing framework.

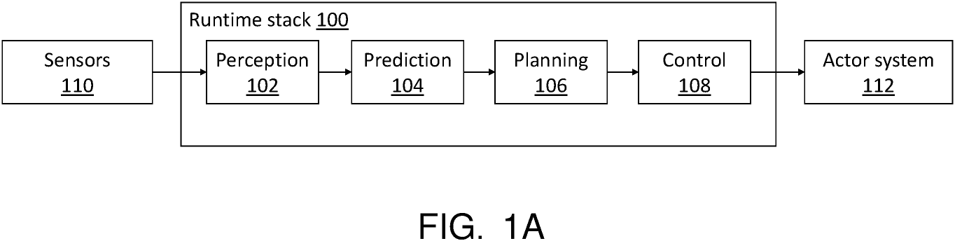

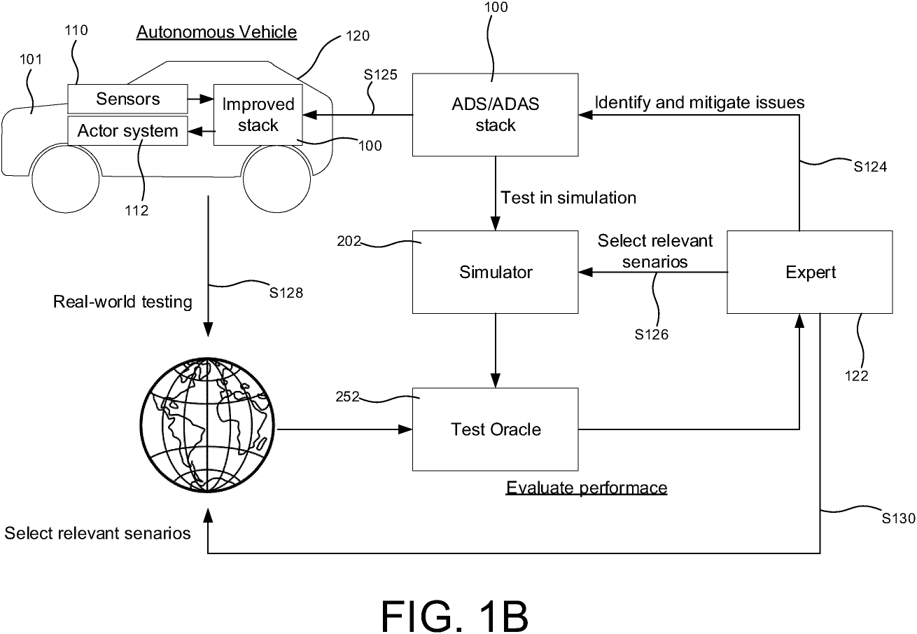

FIG. 1A shows a highly schematic block diagram of a runtime stack 100 for an autonomous vehicle (AV), also referred to herein as an ego vehicle (EV). The run time stack 100 is shown to comprise a perception system 102, a prediction system 104, a planner 106 and a controller 108.

In a real-world context, the perception system 102 would receive sensor outputs from an on-board sensor system 110 of the AV and uses those sensor outputs to detect external agents and measure their physical state, such as their position, velocity, acceleration etc. The on-board sensor system 110 can take different forms but generally comprises a variety of sensors such as image capture devices (cameras/optical sensors), LiDAR and/or RADAR unit(s), satellite-positioning sensor(s) (GPS etc.), motion sensor(s) (accelerometers, gyroscopes etc.) etc., which collectively provide rich sensor data from which it is possible to extract detailed information about the surrounding environment and the state of the AV and any external actors (vehicles, pedestrians, cyclists etc.) within that environment. The sensor outputs typically comprise sensor data of multiple sensor modalities such as stereo images from one or more stereo optical sensors, LiDAR, RADAR etc. Stereo imaging may be used to collect dense depth data, with LiDAR/RADAR etc. proving potentially more accurate but less dense depth data. More generally, depth data collection from multiple sensor modalities may be combined in a way that preferably respects their respective levels of uncertainty (e.g. using Bayesian or non-Bayesian processing or some other statistical process etc.). Multiple stereo pairs of optical sensors may be located around the vehicle e.g. to provide full 360° depth perception.

The perception system 102 comprises multiple perception components which co-operate to interpret the sensor outputs and thereby provide perception outputs to the prediction system 104. External agents may be detected and represented probabilistically in a way that reflects the level of uncertainty in their perception within the perception system 102.

In a simulation context, depending on the nature of the testing – and depending, in particular, on where the stack 100 is sliced – it may or may not be necessary to model the on-board sensor system 100. With higher-level slicing, simulated sensor data is not required therefore complex sensor modelling is not required.

The perception outputs from the perception system 102 are used by the prediction system 104 to predict future behaviour of external actors (agents), such as other vehicles in the vicinity of the AV.

Predictions computed by the prediction system 104 are provided to the planner 106, which uses the predictions to make autonomous driving decisions to be executed by the AV in a given driving scenario. A scenario is represented as a set of scenario description parameters used by the planner 106. A typical scenario would define a drivable area and would also capture predicted movements of any external agents (obstacles, form the AV’s perspective) within the drivable area. The driveable area can be determined using perception outputs from the perception system 102 in combination with map information, such as an HD (high-definition) map. Note, there is a distinction between an “online” scenario description (which refers to information passing up the stack from prediction to planning) and an “offline” scenario description used for the purpose of simulation testing (see below). It will be clear in context which is referred to.

A core function of the planner 106 is the planning of trajectories for the AV (ego trajectories) taking into account predicted agent motion. This may be referred to as maneuver planning. A trajectory is planned in order to carry out a desired goal within a scenario. The goal could for example be to enter a roundabout and leave it at a desired exit; to overtake a vehicle in front; or to stay in a current lane at a target speed (lane following). The goal may, for example, be determined by an autonomous route planner (not shown).

The controller 108 executes the decisions taken by the planner 106 by providing suitable control signals to an on-board actor system 112 of the AV. In particular, the planner 106 plans maneuvers to be taken by the AV and the controller 108 generates control signals in order to execute those maneuvers.

### Example Testing Paradigm

FIG. 1B shows a highly schematic overview of a testing paradigm for autonomous vehicles. An ADS/ADAS stack 100, e.g. of the kind depicted in FIG. 1A, is subject to repeated testing and evaluation in simulation, by running multiple scenario instances in a simulator 202, and evaluating the performance of the stack 100 (and/or individual subs-stacks thereof) in a test oracle 252. The output of the test oracle 252 is informative to an expert 122 (team or individual), allowing them to identify issues in the stack 100 and modify the stack 100 to mitigate those issues (S124). The results also assist an expert 122 in selecting further scenarios for testing (S126), and the process continues, repeatedly modifying, testing and evaluating the performance of the stack 100 in simulation. The improved stack 100 is eventually incorporated (S125) in a real-world AV 101, equipped with a sensor system 110 and an actor system 112. The improved stack 100 typically includes program instructions (software) executed in one or more computer processors of an on-board computer system of the vehicle 101 (not shown). The software of the improved stack is uploaded to the AV 101 at step S125. Step 125 may also involve modifications to the underlying vehicle hardware. On board the AV 101, the improved stack 100 receives sensor data from the sensor system 110 and outputs control signals to the actor system 112. Real-world testing (S128) can be used in combination with simulation-based testing. For example, having reached an acceptable level of performance though the process of simulation testing and stack refinement, appropriate real-world scenarios may be selected (S130), and the performance of the AV 101 in those real scenarios may be captured and similarly evaluated in the test oracle 252.

As mentioned above, a problem in testing AV stacks is determining scenarios for testing which are particularly ‘challenging’, i.e. for which the stack is susceptible to failure. However, a further consideration is whether the stack could have been expected to pass a given ‘challenging’ scenario, or whether that scenario would be impossible to pass even for a hypothetical ‘perfect’ driver. Techniques are described below which provide a way to produce informative outputs from the test oracle which enable the expert 122 to select useful scenarios for testing, where the most useful scenarios for testing to improve the stack are those in which failure could have been avoided.

In particular, techniques are described herein for guiding a search of a scenario space, where the aim is to find the most challenging version(s) (e.g. parameterization(s)) of a scenario, subject to the constraint that the scenario should remain ‘passable’ (that is, failure should not become unavoidable). In the examples below, a version (e.g. parameterization) of scenario is deemed passable when failure is avoidable according to some predetermined acceptable failure model associated with the scenario. In the described implementation, the acceptable failure model is applied to traces of a particular scenario instance, in order to determine whether or not the scenario was passable (for a given parameterization of a simulated scenario, it may not be possible to determine whether that parameterization is passable from the parameter value(s) alone; an instance of the scenario may need to be run based on that parameterization, in order to evaluate the traces against the acceptable failure model). A simpler acceptable failure model could be defined on the scenario description parameters directly. Failure by the stack 100 on a passable scenario is deemed an “unacceptable failure”, whereas failure by the stack 100 on an unpassable scenario is deemed an “acceptable failure”. The aim is to find the most challenging scenarios on which failure is unacceptable.

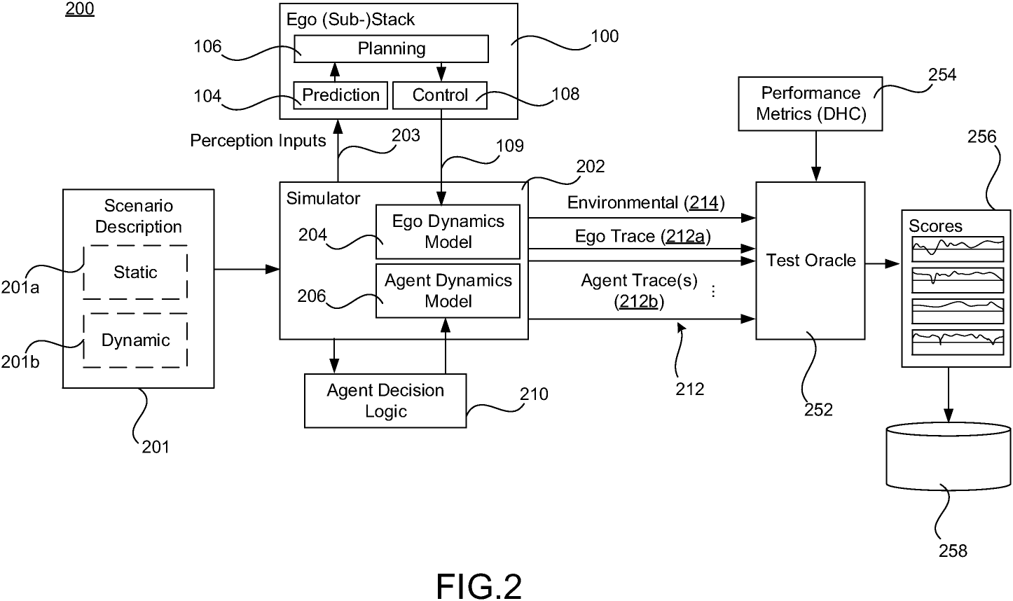

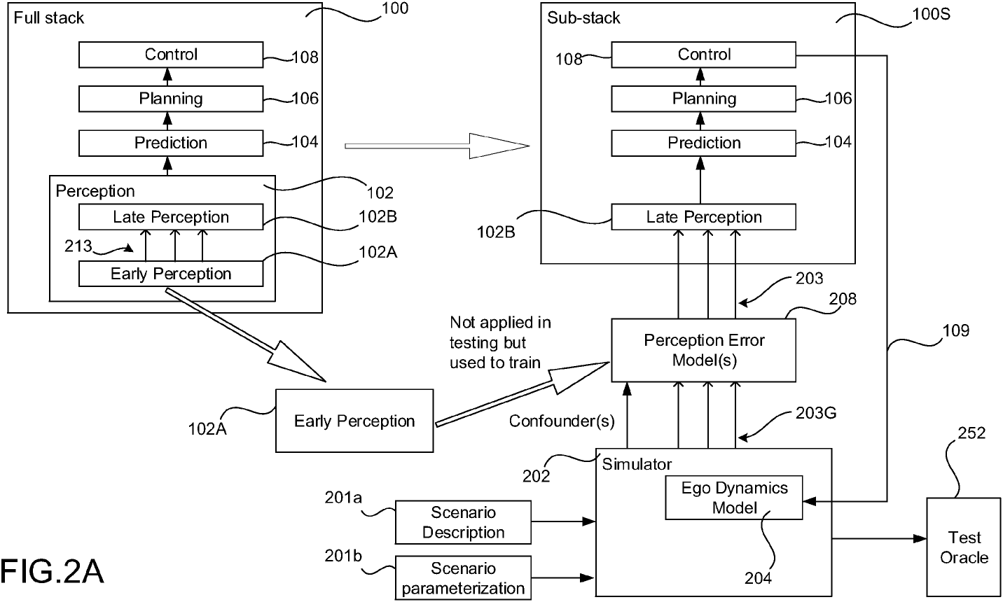

FIG. 2 shows a schematic block diagram of a testing pipeline 200. The testing pipeline 200 is shown to comprise a simulator 202 and a test oracle 252. The simulator 202 runs simulations for the purpose of testing all or part of an AV run time stack.

By way of example only, the description of the testing pipeline 200 makes reference to the runtime stack 100 of FIG. 1A to illustrate some of the underlying principles by example. As discussed, it may be that only a sub-stack of the run-time stack is tested, but for simplicity, the following description refers to the AV stack 100 throughout; noting that what is actually tested might be only a subset of the AV stack 100 of FIG. 1A, depending on how it is sliced for testing. In FIG. 2, reference numeral 100 can therefore denote a full AV stack or only sub-stack depending on the context.

FIG. 2 shows the prediction, planning and control systems 104, 106 and 108 within the AV stack 100 being tested, with simulated perception inputs 203 fed from the simulator 202 to the stack 100. However, this does not necessarily imply that the prediction system 104 operates on those simulated perception inputs 203 directly (though that is one viable slicing, in which case the simulated perception inputs 203 would correspond in form to the final outputs of the perception system 102). For instance, in the example depicted in FIG. 2A and described in detail below, the AV stack 100 is sliced such that a subset of late perception components 102B (only) are included in a tested sub-stack 100S, together with the prediction, planning and control components 104, 106 and 108 (in this case, the simulated perception inputs 203 would correspond to the outputs of the remaining, earlier perception components that are not implemented with the stack 100 during testing). Where the full perception system 102 is implemented in the stack being tested (or, at least, where one or more lower-level perception components that operate on raw sensor data are included), then the simulated perception inputs 203 would comprise simulated sensor data.

The simulated perception inputs 203 are used as a basis for prediction and, ultimately, decision-making by the planner 108. The controller 108, in turn, implements the planner’s decisions by outputting control signals 109. In a real-world context, these control signals would drive the physical actor system 112 of AV. The format and content of the control signals generated in testing are the same as they would be in a real-world context. However, within the testing pipeline 200, these control signals 109 instead drive the ego dynamics model 204 to simulate motion of the ego agent within the simulator 202.

To the extent that external agents exhibit autonomous behaviour/decision making within the simulator 202, some form of agent decision logic 210 is implemented to carry out those decisions and drive external agent dynamics within the simulator 202 accordingly. The agent decision logic 210 may be comparable in complexity to the ego stack 100 itself or it may have a more limited decision-making capability. The aim is to provide sufficiently realistic external agent behaviour within the simulator 202 to be able to usefully test the decision-making capabilities of the ego stack 100. In some contexts, this does not require any agent decision making logic 210 at all (open-loop simulation), and in other contexts useful testing can be provided using relatively limited agent logic 210 such as basic adaptive cruise control (ACC). Similar to the ego stack 100, any agent decision logic 210 is driven by outputs from the simulator 202, which in turn are used to derive inputs to the agent dynamics models 206 as a basis for the agent behaviour simulations.

A simulation of a driving scenario is run in accordance with a scenario description 201, having both static and dynamic layers 201a, 201b.

The static layer 201a defines static elements of a scenario, which would typically include a static road layout.

The dynamic layer 201b defines dynamic information about external agents within the scenario, such as other vehicles, pedestrians, bicycles etc. The extent of the dynamic information provided can vary. For example, the dynamic layer 201b may comprise, for each external agent, a spatial path to be followed by the agent together with one or both of motion data and behaviour data associated with the path.

In simple open-loop simulation, an external actor simply follows the spatial path and motion data defined in the dynamic layer that is non-reactive i.e. does not react to the ego agent within the simulation. Such open-loop simulation can be implemented without any agent decision logic 210.

However, in “closed-loop” simulation, the dynamic layer 201b instead defines at least one behaviour to be followed along a static path (such as an ACC behaviour). In this, case the agent decision logic 210 implements that behaviour within the simulation in a reactive manner, i.e. reactive to the ego agent and/or other external agent(s). Motion data may still be associated with the static path but in this case is less prescriptive and may for example serve as a target along the path. For example, with an ACC behaviour, target speeds may be set along the path which the agent will seek to match, but the agent decision logic 110 might be permitted to reduce the speed of the external agent below the target at any point along the path in order to maintain a target headway from a forward vehicle.

The output of the simulator 202 for a given simulation includes an ego trace 212a of the ego agent and one or more agent traces 212b of the one or more external agents (traces 212).

A trace is a complete history of an agent’s behaviour within a simulation having both spatial and motion components. For example, a trace may take the form of a spatial path having motion data associated with points along the path such as speed, acceleration, jerk (rate of change of acceleration), snap (rate of change of jerk) etc.

Additional information is also provided to supplement and provide context to the traces 212. Such additional information is referred to as “environmental” data 214 which can have both static components (such as road layout) and dynamic components (such as weather conditions to the extent they vary over the course of the simulation).

To an extent, the environmental data 214 may be “passthrough” in that it is directly defined by the scenario description 201 and is unaffected by the outcome of the simulation. For example, the environmental data 214 may include a static road layout that comes from the scenario description 201 directly. However, typically the environmental data 214 would include at least some elements derived within the simulator 202. This could, for example, include simulated weather data, where the simulator 202 is free to change weather conditions as the simulation progresses. In that case, the weather data may be time-dependent, and that time dependency will be reflected in the environmental data 214.

The test oracle 252 receives the traces 212 and the environmental data 214, and scores those outputs against a set of predefined numerical performance metrics to 254. A numerical performance metric 254 is said to “score” a trajectory, where the (numerical) indicates the degree of success or failure. A categorial (e.g. pass/fail) result may be derived from one or multiple scores, e.g. based on one or more failure thresholds. That is, an overall categorial result (e.g. pass or failure) might be based on a single numerical metric 254 or a combination of multiple metrics 254. The term “rule” is used below, in relation to both numerical performance metrics and categorical results, and the meaning shall be clear from the context.

The performance metrics 254 encode what may be referred to herein as a “Digital Highway Code” (DHC). Some examples of suitable performance metrics are given below.

The evaluation of the rules is time-based - a given rule may have a different outcome at different points in the scenario. The scoring is also time-based: for each performance evaluation metric, the test oracle 252 tracks how the value of that metric 254 (the score) changes over time as the simulation progresses. The test oracle 252 provides an output 256 comprising a time sequence 256a of categorical (e.g. pass/fail) results for each rule, and a score-time plot 256b for each performance metric, as described in further detail later. The results and scores 256a, 256b are informative to the expert 122 and can be used to identify and mitigate performance issues within the tested stack 100. The test oracle 252 also provides an overall (aggregate) result for the scenario (e.g. overall pass/fail). The output 256 of the test oracle 252 is stored in a test database 258, in association with information about the scenario to which the output 256 pertains. For example, the output 256 may be stored in association with the scenario description 201. As well as the time-dependent results and scores, an overall score may also be assigned to the scenario and stored as part of the output 256. For example, an aggregate score for each rule (e.g. overall pass/fail) and/or an aggregate result (e.g. pass/fail) across all of the rules.

### Testing Metrics

The performance metrics 254 can be based on various factors, such as distance, speed etc. In the described system, these can mirror a set of applicable road rules, such as the Highway Code applicable to road users in the United Kingdom. The term “Digital Highway Code” (DHC) may be used in relation to the set of performance metrics 254, however, this is merely a convenient shorthand and does not imply any particular jurisdiction. The DHC can be made up of any set of performance metrics 254 that can assess driving performance numerically. As noted, each metric is numerical and time-dependent. The value of a given metric at a partial time is referred to as a score against that metric at that time.

Relatively simple metrics include those based on vehicle speed or acceleration, jerk etc., distance to another agent (e.g. distance to closest cyclist, distance to closest oncoming vehicle, distance to curb, distance to center line etc.). A comfort metric could score the path in terms of acceleration or a first or higher order time derivative of acceleration (jerk, snap etc.). Another form of metric measures progress to a defined goal, such as reaching a particular roundabout exit. A simple progress metric could simply consider time taken to reach a goal. More sophisticated metrics progress metric quantify concepts such as “missed opportunities”, e.g. in a roundabout context, the extent to which an ego vehicle is missing opportunities to join a roundabout.

For each rule, an associated “failure threshold” is defined. An ego agent is said to have failed a given rule if its score against the associated performance metric(s) drops below that threshold.

Not all of the metrics 254 will necessarily apply to a given scenario. For example, a subset of the metrics 254 may be selected that are applicable to a given scenario. An applicable subset of metrics can be selected by the test oracle 252 in dependence on one or both of the environmental data 214 pertaining to the scenario being considered, and the scenario description 201 used to simulate the scenario. For example, certain metrics may only be applicable to roundabouts or junctions etc., or to certain weather or lighting conditions.

One or both of the metrics 254 and their associated failure thresholds may be adapted to a given scenario. For example, speed-based metrics and/or their associated performance functions may be adapted in dependence on an applicable speed limit but also weather/lighting conditions etc.

### Test Orchestration

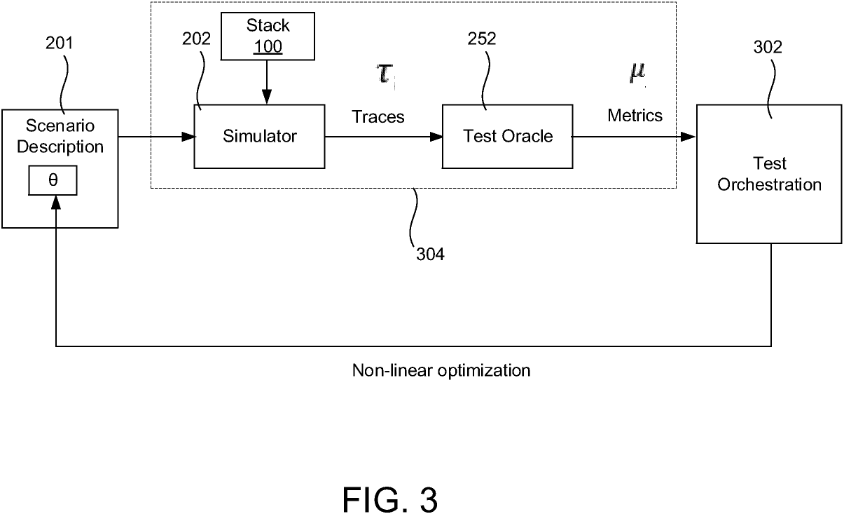

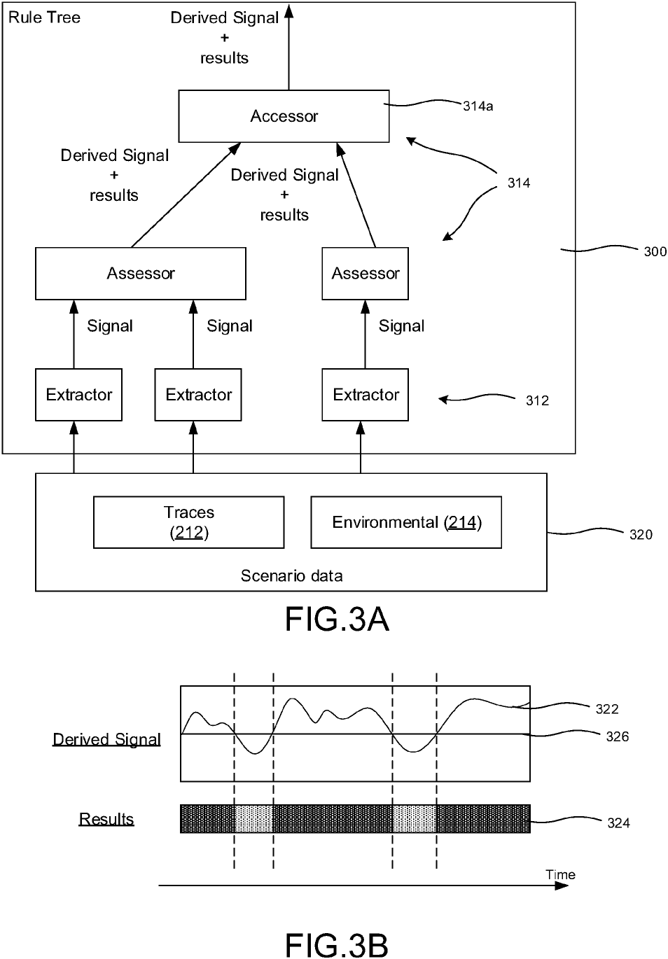

FIG. 3 shows further details of the testing pipeline 200. A test orchestration component 302 is shown, which is responsible for setting parameters θ of a scenario description 201 (scenario parameters or parameters for conciseness) in order to test variations of the scenario it defines. The parameters θ are defined in a “scenario space”, which may have a high dimensionality (i.e. there may be a large number of adjustable scenario parameters θ).

In the field of autonomous driving, the term “fuzzing” is sometimes used to refer to testing of this nature. This typically involves some random perturbation of scenario parameters. For example, fuzzing has been used to explore real-world instance of recorded failures (e.g. necessitating test driver intervention), by recreating the scenario, and analysing the effect of slight random perturbations to the scenario parameters.

In the present context, an aim is to move away from “fuzzing” in this sense, to more structured scenario-exploration. In a simulation based on a large scenario space (i.e. with a large number of adjustable scenario parameters), randomized fuzzing is highly inefficient, because of the sheer number of slightly different combinations of parameters that need to be tried.

The test orchestration component 302 leverages the numerical performance metrics 254, with the aim of efficiently determining instances of “maximum failure”. That is, finding particular variations of a scenario when the stack performs worst with respect to one or more of the metrics 254. To do so, this problem is formulated as a non-linear optimization; the test orchestration component 302 performs a structured search of the scenario space with the aim of substantially “optimizing” the scenario parameters θ, i.e. finding particular combination of parameter values for which the stack 100 exhibits the worst performance with respect to the applicable performance metric(s). The aim is to find variations of a scenario that are most challenging for the stack, in order to efficiently identify performance issues. How to define poor stack performance for different scenario parameters such that useful scenarios can be identified for further testing and improvement of the stack is described in more detail below.

As depicted in FIG. 3, for a given set of scenario parameters θ (i.e. a particular combination of values of the scenario parameters θ), the simulator 202 will produce a set of traces τ (the trace output), which in turn are scored against the set or subset of applicable performance metrics, µ.

For the purpose of tuning the scenario parameters θ, the portion of the pipeline that includes the simulator 202, stack 100 under test and the test oracle 252 – denoted by reference numeral 304 – is treated as a non-linear function of the scenario parameters θ (the input), i.e. as a “black box” that takes the scenario parameters θ and computes the corresponding scores in respect of the applicable performance metric(s) 254. Although not depicted, where applicable, this portion 304 would also include the agent decision logic 210, as this can also affect the traces and hence the scores.

### Test Oracle Rules

The performance evaluation rules are constructed as computational graphs (rule trees) to be applied within the test oracle. Unless otherwise indicated, the term “rule tree” herein refers to the computational graph that is configured to implement a given rule. Each rule is constructed as a rule tree, and a set of multiple rules may be referred to as a “forest” of multiple rule trees.

FIG. 3A shows an example of a rule tree 310 constructed from a combination of extractor nodes (leaf objects) 312 and assessor nodes (non-leaf objects) 314. Each extractor node 312 extracts a time-varying numerical (e.g. floating point) signal (score), based on the one or more performance metrics 254, from a set of scenario data 320, such as the trace output laid out above. The scenario data 320 has been obtained by deploying a trajectory planner (such as the planner 106 of FIG. 1A) in a scenario, and is shown to comprise ego and agent traces 212 as well as contextual data 214.

Each assessor node 314 is shown to have at least one child object (node), where each child object is one of the extractor nodes 312 or another one of the assessor nodes 314. Each assessor node receives output(s) from its child node(s) and applies an assessor function to those output(s). The output of the assessor function is a time-series of categorical results. The following examples consider simple binary pass/fail results, but the techniques can be readily extended to non-binary results. Each assessor function assesses the output(s) of its child node(s) against a predetermined atomic rule. Such rules can be flexibly combined in accordance with a desired safety model.

In addition, each assessor node 314 derives a time-varying numerical signal from the output(s) of its child node(s), which is related to the categorical results by a threshold condition (see below).

A top-level root node 314a is an assessor node that is not a child node of any other node. The top-level node 314a outputs a final sequence of results, and its descendants (i.e. nodes that are direct or indirect children of the top-level node 314a) provide the underlying signals and intermediate results.

FIG. 3B visually depicts an example of a derived signal 322 and a corresponding time-series of results 324 computed by an assessor node 314. The results 324 are correlated with the derived signal 322, in that a pass result is returned when (and only when) the derived signal exceeds a failure threshold 326. As will be appreciated, this is merely one example of a threshold condition that relates a time-sequence of results to a corresponding signal.

Signals extracted directly from the scenario data 320 by the extractor nodes 312 may be referred to as “raw” signals, to distinguish from “derived” signals computed by assessor nodes 314. Results and raw/derived signals may be discretized in time.

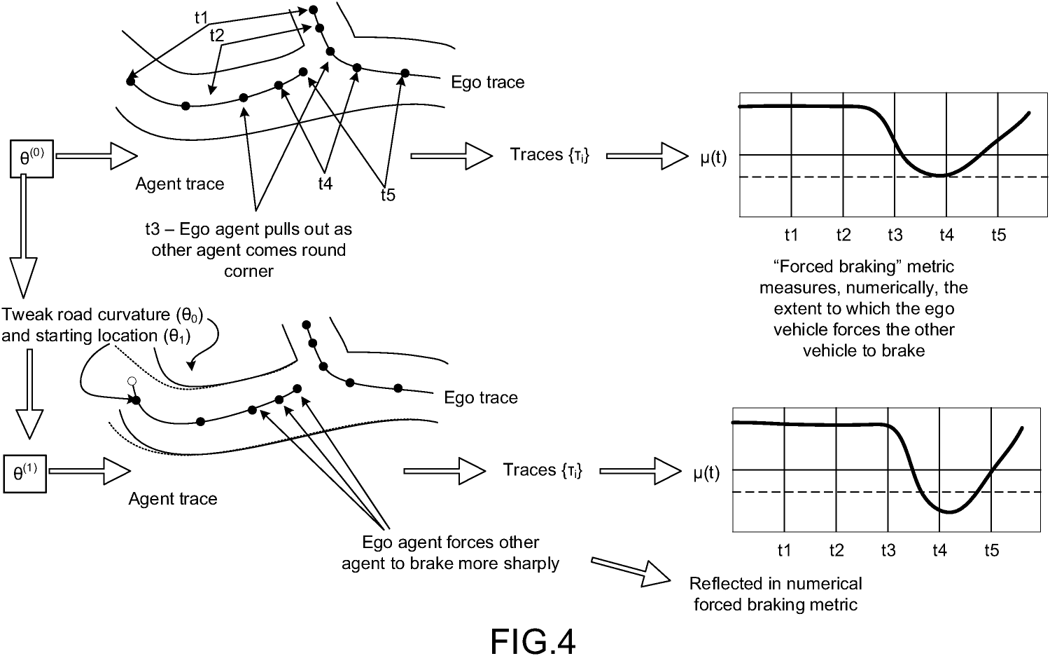

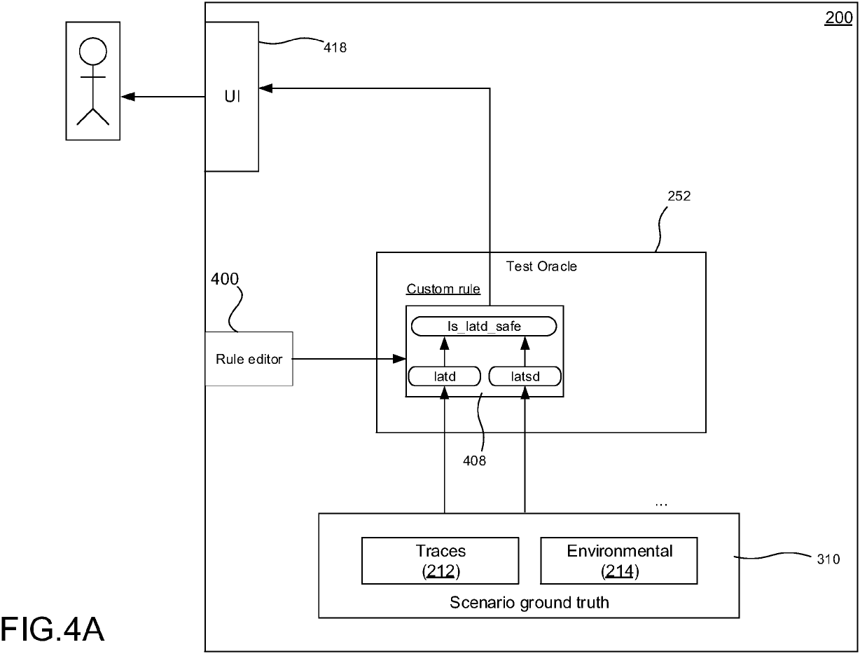

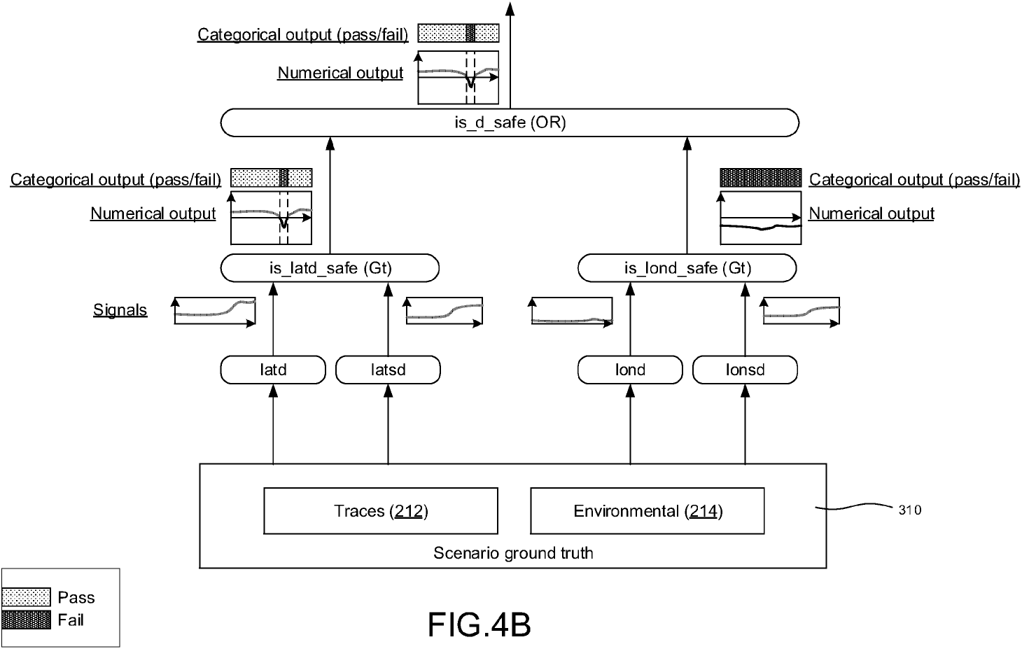

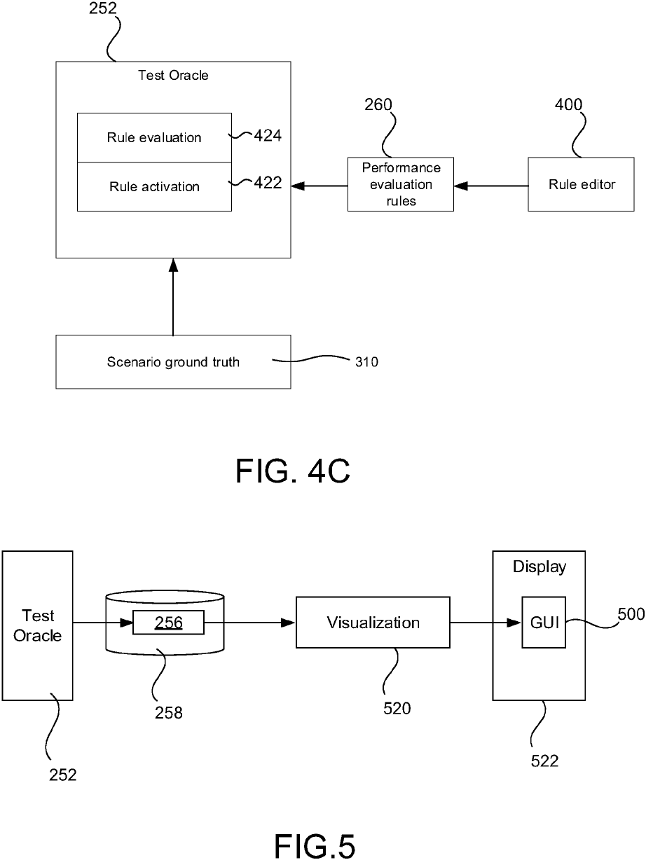

FIG. 4 provides an example illustrating the principles of the non-linear optimization described above with reference to FIG. 3. This depicts a scenario, in which an ego agent has the goal of joining a major road from a minor road. The major road is curved, in a way that creates a “blind corner” for the ego vehicle, that restricts the visibility of an oncoming vehicle (the other agent). For simplicity, only two parameters are considered: road curvature, θ₀, and starting location of the oncoming vehicle along the road, θ₁. However, the techniques can be applied to a larger number of scenario parameters, including scenarios with hundreds or thousands of adjustable parameters.

A “forced braking” metric is considered in this example. This measures an extent to which the oncoming vehicle is forced to brake by the ego vehicle. This could be implemented, in simulation, by applying a braking behaviour to the other agent, which is implemented in a reactive manner by the agent decision logic 210. To implement the forced braking metric, target motion values could be defined along the other vehicle’s path (e.g. speed, acceleration etc.) and the forced braking metric could measure deviation from the target motion values. A certain amount of forced braking may be acceptable; however, the defined failure threshold would represent the point at which the ego vehicle has caused the other vehicle to slow down or brake by an unacceptable amount.

In this simple example, it is reasonable to suppose that both the road curvature θ₀ and the starting location of the oncoming vehicle θ₁ might be relevant to the forced braking metric; FIG. 4 depicts two variations of the scenario. In both variations, the stack 100 causes the ego vehicle to pull out in front of the other vehicle, causing it to brake. However, in the second depicted variation, with slightly increased path curvature and with the oncoming vehicle starting slightly further along the road, the oncoming vehicle is forced to brake more aggressively, resulting in worse performance with respect to the forced braking metric.

In this example, an aim of the test orchestration component 302 would be to find substantially “optimal” values of the road curvature and starting location parameters, θ₀ and θ₁, that result in the worst performance of the stack 100 with respect to the forced braking metric. “Worst performance” can be quantified in any suitable way, e.g. the aim might be to find the parameters that result in the worst instantaneous score (the global minima of the metric in this example, where a decreasing score indicates worse performance, though this is an arbitrary design choice), or worst averaged score.

FIG. 4A shows an example of a rule tree implemented within the testing pipeline 200.

A rule editor 400 is provided for constructing rules to be implemented with the test oracle 252. The rule editor 400 receives rule creation inputs from a user (who may or may not be the end-user of the system). In the present example, the rule creation inputs are coded in a domain specific language (DSL) and define at least one rule graph 408 to be implemented within the test oracle 252. The rules are logical rules in the following examples, with TRUE and FALSE representing pass and failure respectively (as will be appreciated, this is purely a design choice).

The following examples consider rules that are formulated using combinations of atomic logic predicates. Examples of basic atomic predicates include elementary logic gates (OR, AND etc.), and logical functions such as “greater than”, (Gt(a,b)) (which returns TRUE when a is greater than b, and false otherwise).

A Gt function is to implement a safe lateral distance rule between an ego agent and another agent in the scenario (having agent identifier “other_agent_id”). Two extractor nodes (latd, latsd) apply LateralDistance and LateralSafeDistance extractor functions respectively. Those functions operate directly on the scenario ground truth 310 to extract, respectively, a time-varying lateral distance signal (measuring a lateral distance between the ego agent and the identified other agent), and a time-varying safe lateral distance signal for the ego agent and the identified other agent. The safe lateral distance signal could depend on various factors, such as the speed of the ego agent and the speed of the other agent (captured in the traces 212), and environmental conditions (e.g. weather, lighting, road type etc.) captured in the contextual data 214.

An assessor node (is_latd_safe) is a parent to the latd and latsd extractor nodes, and is mapped to the Gt atomic predicate. Accordingly, when the rule tree 408 is implemented, the is_latd_safe assessor node applies the Gt function to the outputs of the latd and latsd extractor nodes, in order to compute a true/false result for each timestep of the scenario, returning TRUE for each time step at which the latd signal exceeds the latsd signal and FALSE otherwise. In this manner, a “safe lateral distance” rule has been constructed from atomic extractor functions and predicates; the ego agent fails the safe lateral distance rule when the lateral distance reaches or falls below the safe lateral distance threshold. As will be appreciated, this is a very simple example of a rule tree. Rules of arbitrary complexity can be constructed according to the same principles.

The test oracle 252 applies the rule tree 408 to the scenario ground truth 310, and provides the results via a user interface (UI) 418.

FIG. 4B shows an example of a rule tree that includes a lateral distance branch corresponding to that of FIG. 4A. Additionally, the rule tree includes a longitudinal distance branch, and a top-level OR predicate (safe distance node, is_d_safe) to implement a safe distance metric. Similar to the lateral distance branch, the longitudinal distance brand extracts longitudinal distance and longitudinal distance threshold signals from the scenario data (extractor nodes lond and lonsd respectively), and a longitudinal safety assessor node (is_lond_safe) returns TRUE when the longitudinal distance is above the safe longitudinal distance threshold. The top-level OR node returns TRUE when one or both of the lateral and longitudinal distances is safe (below the applicable threshold), and FALSE if neither is safe.

In this context, it is sufficient for only one of the distances to exceed the safety threshold (e.g. if two vehicles are driving in adjacent lanes, their longitudinal separation is zero or close to zero when they are side-by-side; but that situation is not unsafe if those vehicles have sufficient lateral separation).

The numerical output of the top-level node could, for example, be a time-varying robustness score.

Different rule trees can be constructed, e.g. to implement different rules of a given safety model, to implement different safety models, or to apply rules selectively to different scenarios (in a given safety model, not every rule will necessarily be applicable to every scenario; with this approach, different rules or combinations of rules can be applied to different scenarios). Within this framework, rules can also be constructed for evaluating comfort (e.g. based on instantaneous acceleration and/or jerk along the trajectory), progress (e.g. based on time taken to reach a defined goal) etc.

The above examples consider simple logical predicates evaluated on results or signals at a single time instance, such as OR, AND, Gt etc. However, in practice, it may be desirable to formulate certain rules in terms of temporal logic.

Hekmatnejad et al., “Encoding and Monitoring Responsibility Sensitive Safety Rules for Automated Vehicles in Signal Temporal Logic” (2019), MEMOCODE ‘19: Proceedings of the 17th ACM-IEEE International Conference on Formal Methods and Models for System Design (incorporated herein by reference in its entirety) discloses a signal temporal logic (STL) encoding of the RSS safety rules. Temporal logic provides a formal framework for constructing predicates that are qualified in terms of time. This means that the result computed by an assessor at a given time instant can depend on results and/or signal values at another time instant(s).

For example, a requirement of the safety model may be that an ego agent responds to a certain event within a set time frame. Such rules can be encoded in a similar manner, using temporal logic predicates within the rule tree.

In the above examples, the performance of the stack 100 is evaluated at each time step of a scenario. An overall test result (e.g. pass/fail) can be derived from this - for example, certain rules (e.g. safety-critical rules) may result in an overall failure if the rule is failed at any time step within the scenario (that is, the rule must be passed at every time step to obtain an overall pass on the scenario). For other types of rule, the overall pass/fail criteria may be “softer” (e.g. failure may only be triggered for a certain rule if that rule is failed over some number of sequential time steps), and such criteria may be context dependent.

### Rule Evaluation Hierarchy

FIG. 4C schematically depicts a hierarchy of rule evaluation implemented within the test oracle 252. A set of rules 260 is received for implementation in the test oracle 252.

Certain rules apply only to the ego agent (an example being a comfort rule that assesses whether or not some maximum acceleration or jerk threshold is exceeded by the ego agent at any given time instant).

Other rules pertain to the interaction of the ego agent with other agents (for example, a “no collision” rule or the safe distance rule considered above). Each such rule is evaluated in a pairwise fashion between the ego agent and each other agent. As another example, a “pedestrian emergency braking” rule may only be activated when a pedestrian walks out in front of the ego vehicle, and only in respect of that pedestrian agent.

Not every rule will necessarily be applicable to every scenario, and some rules may only be applicable for part of a scenario. Rule activation logic 422 within the test oracle 422 determines if and when each of the rules 260 is applicable to the scenario in question, and selectively activates rules as and when they apply. A rule may, therefore, remain active for the entirety of a scenario, may never be activated for a given scenario, or may be activated for only some of the scenario. Moreover, a rule may be evaluated for different numbers of agents at different points in the scenario. Selectively activating rules in this manner can significantly increase the efficiency of the test oracle 252.

The activation or deactivation of a given rule may be dependent on the activation/deactivation of one or more other rules. For example, an “optimal comfort” rule may be deemed inapplicable when the pedestrian emergency braking rule is activated (because the pedestrian’s safety is the primary concern), and the former may be deactivated whenever the latter is active.

Rule evaluation logic 424 evaluates each active rule for any time period(s) it remains active. Each interactive rule is evaluated in a pairwise fashion between the ego agent and any other agent to which it applies.

There may also be a degree of interdependency in the application of the rules. For example, another way to address the relationship between a comfort rule and an emergency braking rule would be to increase a jerk/acceleration threshold of the comfort rule whenever the emergency braking rule is activated for at least one other agent.

Whilst pass/fail results have been considered, rules may be non-binary. For example, two categories for failure – “acceptable” and “unacceptable” – may be introduced. Again, considering the relationship between a comfort rule and an emergency braking rule, an acceptable failure on a comfort rule may occur when the rule is failed but at a time when an emergency braking rule was active. Interdependency between rules can, therefore, be handled in various ways.

The activation criteria for the rules 254 can be specified in the rule creation code provided to the rule editor 400, as can the nature of any rule interdependencies and the mechanism(s) for implementing those interdependencies.

### Graphical User Interface

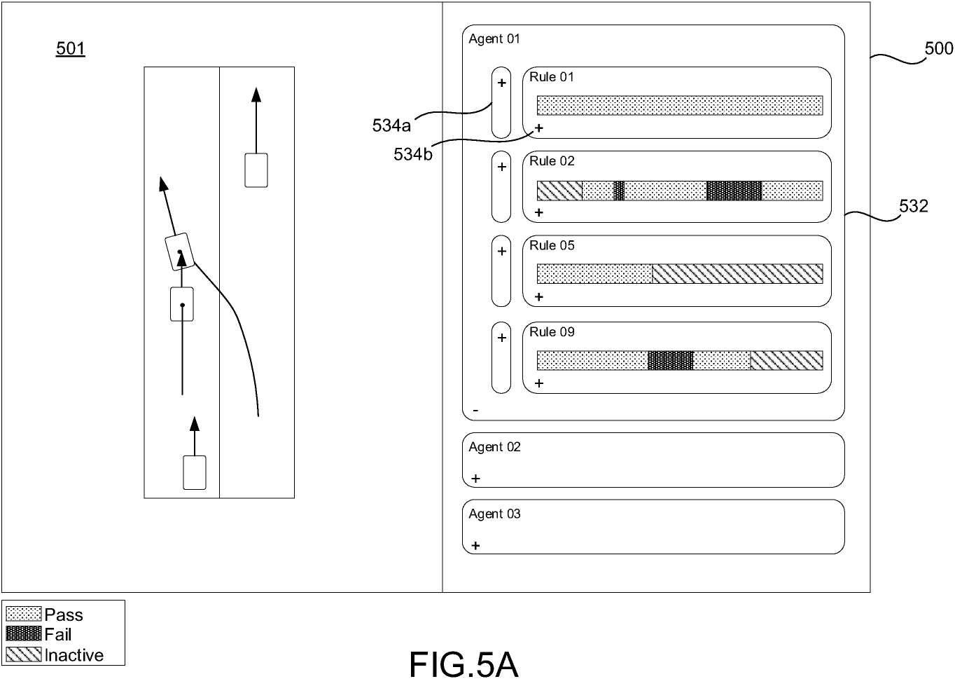

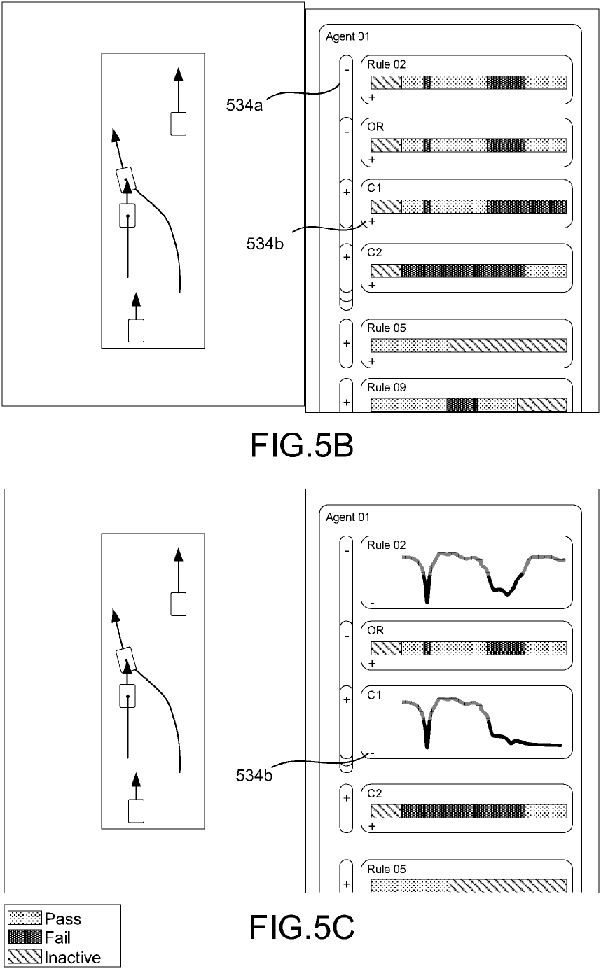

FIG. 5 shows a schematic block diagram of a visualization component 520. The visualization component is shown having an input connected to the test database 258 for rendering the outputs 256 of the test oracle 252 on a graphical user interface (GUI) 500. The GUI is rendered on a display system 522.

FIG. 5A shows an example view of the GUI 500. The view pertains to a particular scenario containing multiple agents. In this example, the test oracle output 526 pertains to multiple external agents, and the results are organized according to agent. For each agent, a time-series of results is available for each rule applicable to that agent at some point in the scenario. The visual representation of the results is referred to as a “rule timeline”. In the depicted example, a summary view has been selected for “Agent 01”, causing the “top-level” results computed to be displayed for each applicable rule. There are the top-level results computed at the root node of each rule tree. Colour coding is used to differentiate between periods when the rule is inactive for that agent, active and passes, and active and failed.

A first selectable element 534a is provided for each time-series of results. This allows lower-level results of the rule tree to be accessed, i.e. as computed lower down in the rule tree.

FIG. 5B shows a first expanded view of the results for “Rule 02”, in which the results of lower-level nodes are also visualized. For example, for a “safe distance” rule, the results of the “is_latd_safe” node and the “is_lond_safe” nodes may be visualized (labelled “C1” and “C2” in FIG. 5B). In the first expanded view of Rule 02, it can be seen that success/failure on Rule 02 is defined by a logical OR relationship between results C1 and C2; Rule 02 is failed only when failure is obtained on both C1 and C2 (as in the “safe distance” rule above).

A second selectable element 534b is provided for each time-series of results, that allows the associated numerical performance scores 254 to be accessed.

FIG. 5C shows a second expanded view, in which the results for Rule 02 and the “C1” results have been expanded to reveal the associated scores for time period(s) in which those rules are active for Agent 01. The scores are displayed as a visual score-time plot that is similarly colour coded to denote pass/fail.

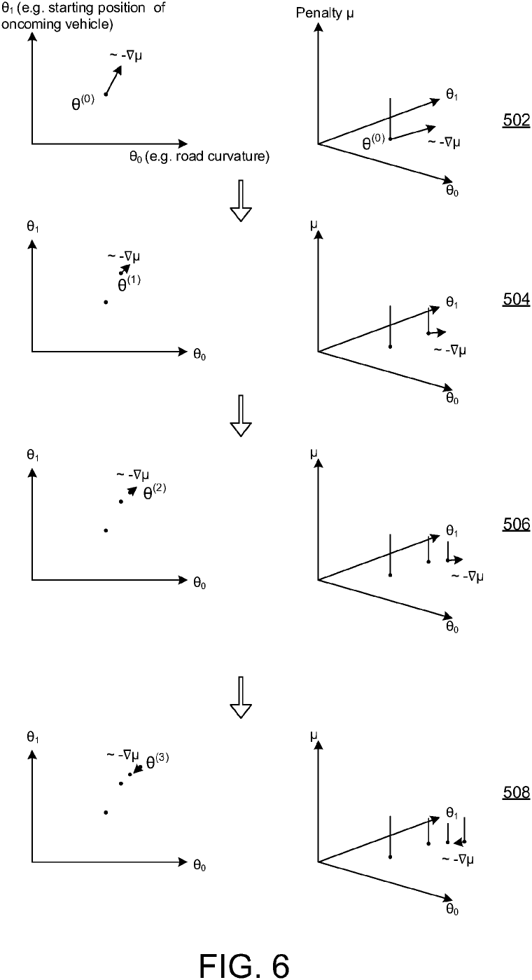

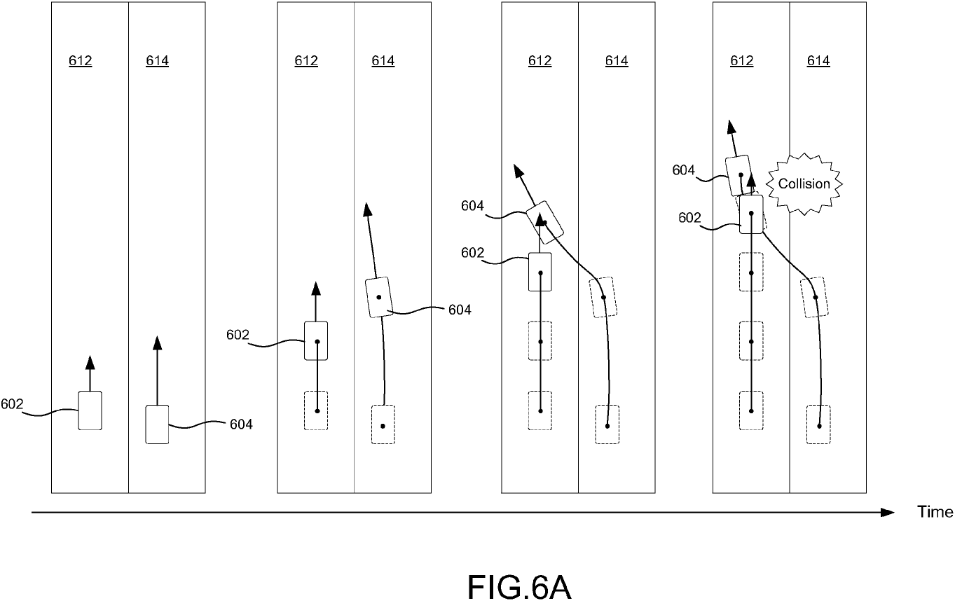

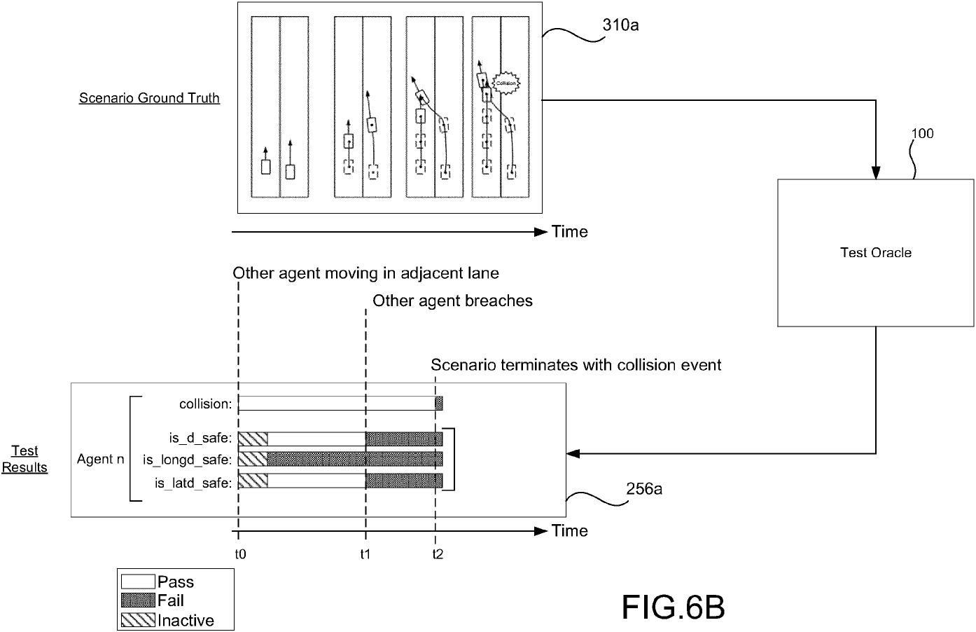

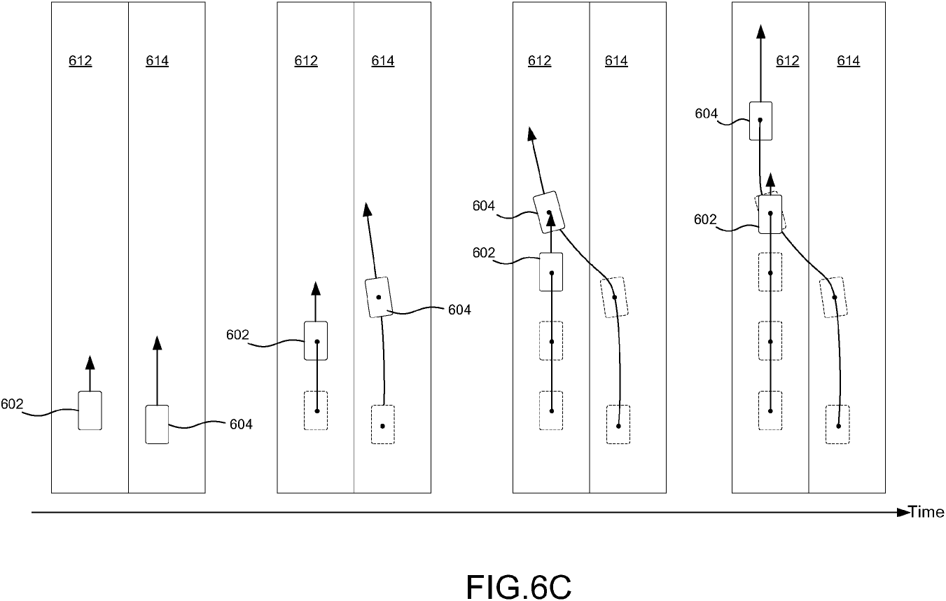

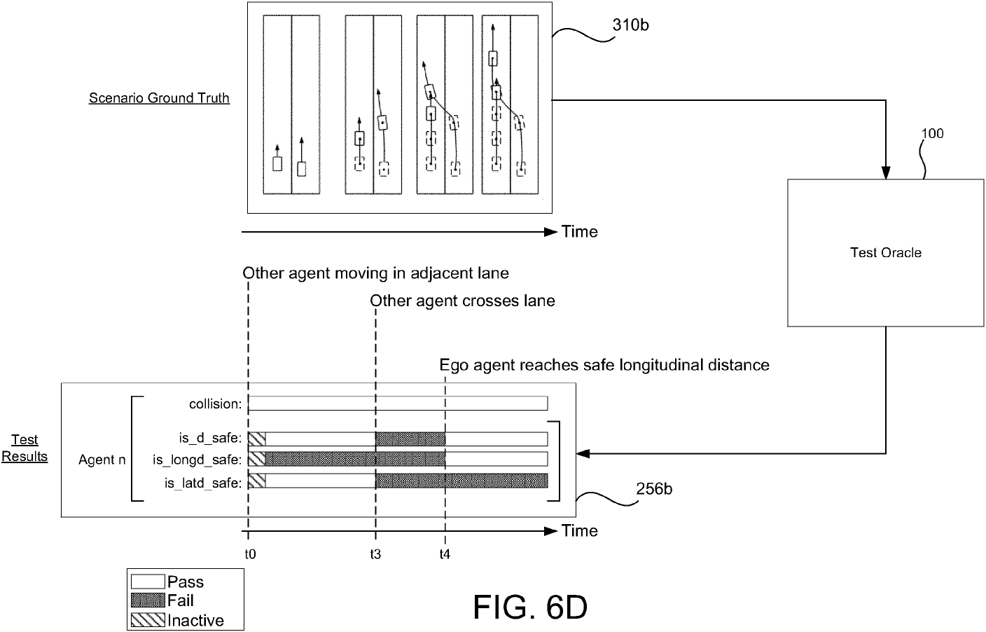

FIG. 6 shows one way in which these concepts can be applied within a structured non-linear optimization framework. This example uses gradient-based optimization, such as gradient descent or gradient ascent (depending on how the metrics are defined).

This gradient-based approach systematically explores the search space based on a gradient of the metric with respect to the scenario parameters θ.

The purpose is to test the existing stack 100, by adapting the scenario parameters θ whilst the parameters of the stack 100 remain fixed (in contrast to, say, end-to-end driving where the purpose is to train a stack end to end, by adjusting parameters of the stack during training with respect to a fixed set of training examples). As noted, the aim is to efficiently find particular combination(s) of the scenario parameters θ that cause the worst performance of the stack 100 with respect to the metric under consideration.

The example depicted in FIG. 6 uses a form of gradient descent. Starting from an initial parameter combination θ⁽⁰⁾ (step 502), which is an initial point in the scenario space, the gradient of a performance function µ(θ) is used to guide a search of the scenario space for a point (parameter combination) that is “optimal” in the sense of maximizing the extent of failure on one or more of the defined performance metrics 254.

Superscripts are used to denote a particular iteration (step) of the optimization, whereas subscripts denote individual scenario parameters. Hence, θ⁽ⁿ⁾ denotes a particular combination of values,

$$\left({θ}_{0}^{\left(n\right)} , {θ}_{1}^{\left(n\right)}\right) ,$$

of the scenario parameters (θ₀, θ₁).

In the above examples, the performance metrics 254 are time-varying functions. The performance function µ(θ), which is a time-independent function of the scenario parameters θ in this example, is derived from one or more of the time-dependent metrics 254, for example as time-average or other aggregation, or at a global minima or maxima. The performance metric µ(θ) is derived from a single performance metric in this example, but could be an aggregation of multiple performance metrics 254.

The metric(s) 254 and the performance function µ(θ) are numerical and locally continuous, in that small changes in the scenario parameters θ, at least within certain regions of the scenario space, result in substantially continuous changes in µ(θ), allowing small changes in the parameters θ within each such region of the scenario space to be mapped onto continuous changes in the performance function µ(θ). In practice, when considered across the whole of the scenario space, the portion of the pipeline 304 depicted in FIG. 3 may be a highly non-linear system, in that small changes to the scenario parameters θ could result in very different agent behaviour (and hence very different performance metrics 254). Taking the example of FIG. 4, as the starting location of the other vehicle θ₁ is moved closer and closer to the junction at which the ego agent is located, there may come a point at which the perception of the oncoming vehicle by the ego agent causes the stack 100 to delay pulling out until the oncoming vehicle has passed - as opposed to pulling out in front of the oncoming vehicle, causing it to aggressively brake in response, which might be the response of the stack 100 for a slightly earlier starting location θ₁. This is an example of a highly non-linear response to a small change in the scenario parameter θ₁, which would result in a discontinuous jump in a numerical penalty µ(θ) derived from the forced braking metric.

However, prior to that point, the penalty µ(θ) might exhibit a substantially continuous response to changes in θ₁; if the stack pulls out because it fails to perceive the oncoming vehicle in time, then the less distance the oncoming vehicle has to brake, the more aggressive the braking it will require to stop in time.

Returning to step 502 of FIG. 6, the gradient of the performance function at the initial point in the scenario space, ∇µ(θ⁽⁰⁾), is computed or estimated, and a step is taken in the scenario space in proportion to the negative gradient -∇µ(θ⁽⁰⁾), in order to determine a scenario parameter combination θ⁽¹⁾ for the next iteration. This is repeated for each iteration, until some convergence criteria (or other terminating criteria) are met, with the starting point in scenario space, θ⁽ⁿ⁺¹⁾ for each iteration n + 1 determined based on the gradient of the performance function, ∇µ(θ⁽ⁿ⁻¹⁾), in the previous iteration n - 1.

Gradient-descent is well known per se, and is the therefore not described in further detail. However, it is important to note the context in which this methodology is applied. As noted, this is not about training the stack 100. The parameters θ define the scenario to be simulated. The aim is to vary the simulated scenario in a structured way, in order to find the worst failure cases. In this sense, this is a “falsification” method that aims to expose the stack 100 to the most challenging simulated scenarios more efficiently and systematically than existing scenario fuzzing techniques.

The present techniques do not require the simulator 202 or the stack 100 (or, more precisely, the portion of the pipeline 304 depicted in FIG. 3) to be strictly differentiable, or differentiable in any analytical sense. The only requirement is that, within localized regions of the scenario space, the performance function µ(θ) is substantially continuous such that a meaningful gradient can be estimated. The gradient can be estimated numerically. In practice this would mean, given a point θ⁽ⁿ⁾ in the scenario space, running additional simulations, θ⁽ⁿ⁾ + δ, with different and small perturbations δ (i.e. slight changes to the scenario parameters), and fitting a gradient to the resulting values of µ(θ⁽ⁿ⁾ + δ). The perturbations δ should be small enough that the response of the performance function µ(θ) remains substantially continuous.

For a performance function that is globally discontinuous (i.e. over the scenario space as a whole), but continuous over localised regions of the scenario space, the search can be modified to include a check at each iteration to confine the search to a single localized region of the scenario space (i.e. over which the performance function remains substantially continuous). This could be implemented as a check in each iteration n + 1 as to whether the updated parameters θ⁽ⁿ⁺¹⁾ are outside of that localized search region, e.g. if the magnitude of difference in the performance function

$$\left|μ \left({θ}^{\left(n - 1\right)}\right) - μ \left({θ}^{\left(n\right)}\right)\right|$$

exceeds some threshold, θ⁽ⁿ⁺¹⁾ could be classed as outside of the localized region of the scenario space under consideration, and different scenario parameters could be attempted instead.

As will be appreciated, gradient descent is just one example of a suitable optimization technique that can be applied to a non-linear system. Other forms of non-linear optimization may be applied in this context, in order to search for scenario parameters that are optimal in the sense of causing the worst performance of the stack 100 under testing.

In some circumstances, it may be appropriate to formulate this as a constrained optimization, in order to restrict the search space to physically feasible scenarios. For example, taking the example of road curvature θ₀, feasibility constraints could be placed on this parameter, to prevent simulations based on unrealistic road curvature.

For simplicity, the above examples relate to optimising with respect to a function based on a single performance metric. However, as described above, the test oracle may define a rule hierarchy in which multiple rules may be applied at different times within a scenario, and a numerical output based on any of these rules may be used with a gradient-based method as described above to determine an ‘optimal’ set of parameters that result in the ‘worst’ performance. In this case, the optimization may be over a “composite” (aggregate) metric that is defined as a combination of multiple component metrics.

In addition to metrics derived directly from scenario data, the performance score may be defined so as to also consider the relative importance of testing scenarios for which the stack could have performed better over those scenarios where the stack could not have avoided a poor outcome. This allows an expert, such as the test orchestrator 302, to choose appropriate scenarios for future testing which can lead to improvement of the stack.

FIG. 6A depicts a first instance of a cut-in scenario in the simulator 202 that terminates in a collision event between an ego vehicle 602 and another vehicle 604. The cut-in scenario is characterized as a multi-lane driving scenario, in which the ego vehicle 602 is moving along a first lane 612 (the ego lane) and the other vehicle 604 is initially moving along a second, adjacent lane 604. At some point in the scenario, the other vehicle 604 moves from the adjacent lane 614 into the ego lane 612 ahead of the ego vehicle 602 (the cut-in distance). In this scenario, the ego vehicle 602 is unable to avoid colliding with the other vehicle 604. The first scenario instance terminates in response to the collision event.

FIG. 6B depicts an example of a first oracle output 256a obtained from ground truth 310a of the first scenario instance. A “no collision” rule is evaluated over the duration of the scenario between the ego vehicle 602 and the other vehicle 604. The collision event results in failure on this rule at the end of the scenario. In addition, the “safe distance” rule of FIG. 4B is evaluated. As the other vehicle 604 moves laterally closer to the ego vehicle 602, there comes a point in time (t1) when both the safe lateral distance and safe longitudinal distance thresholds are breached, resulting in failure on the safe distance rule that persists up to the collision event at time t2.

FIG. 6C depicts a second instance of the cut-in scenario. In the second instance, the cut-in event does not result in a collision, and the ego vehicle 602 is able to reach a safe distance behind the other vehicle 604 following the cut-in event.

FIG. 6D depicts an example of a second oracle output 256b obtained from ground truth 310b of the second scenario instance. In this case, the “no collision” rule is passed throughout. The safe distance rule is breached at time t3 when the lateral distance between the ego vehicle 602 and the other vehicle 604 becomes unsafe. However, at time t4, the ego vehicle 602 manages to reach a safe distance behind the other vehicle 604. Therefore, the safe distance rule is only failed between time t3 and time t4.

### Blame Assessment

Blame or responsibility is an important concept in an interactive agent scenario. If a failure occurs in a scenario run, the question of whether the ego agent is at fault in a given scenario is important in determining whether or not an undesired event arose from a problem within the stack 100 under test. In one sense, blame is an intuitive concept. However, it is a challenging concept to apply in the context of a formal safety model and rules-based performance testing more generally.

For example, in the first scenario instance of FIG. 6A, the collision event could be the responsibility of the ego agent 602 or the other agent 604 depending on the circumstances of the cut-in action by the other agent 604.

An extension of the testing framework will now be described that formalizes the concept blame and thus allows blame to be assessed objectively in a similarly rigorous and unambiguous manner.

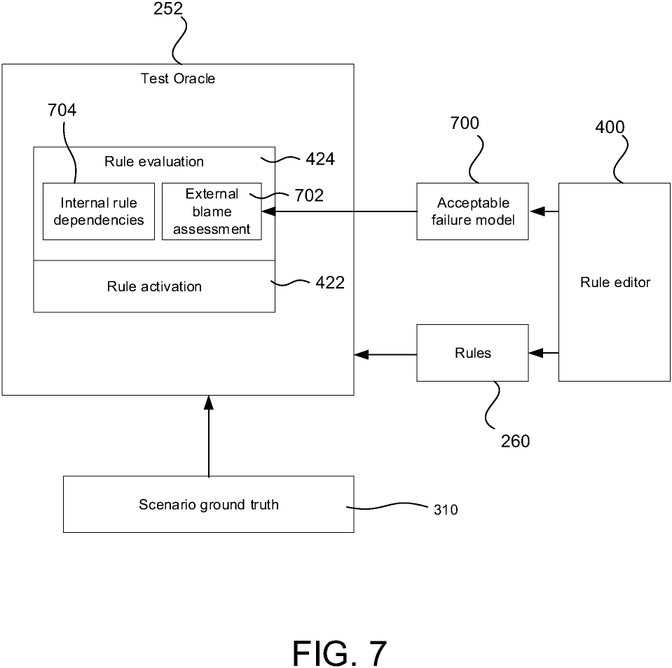

FIG. 7 shows an extension of the test oracle 252 to incorporate “external” blame assessment logic 702. When a failure occurs on a rule for a given agent pairing (the ego agent and another agent), an assessment is made as to whether the ego agent or the other agent is responsible for the failure. The following examples consider collision events, characterized as failure on a top-level “no collision” rule. However, the same principles can be applied to any type of rule, anywhere in the hierarchy of the rules that are applicable to a given scenario run. In the following description, a failure on a rule that is determined to be the responsibility of the other agent rather than the ego agent may be termed an “acceptable failure”. The notion of a formal safety model is extended to include an “acceptable failure” model - the aim being to formally distinguish between failures that the ego agent should have been able to prevent, from failures that no ego agent could reasonably be expected to prevent.

Note, the external blame assessment is distinct from any “internal” evaluation of rule interdependencies by any internal rule evaluation logic 704. For example, as described above, failure on a given comfort rule may, in some implementations, be deemed acceptable or justified in a more general sense when another rule that takes precedence over the comfort rule is activated, such as an emergency braking rule.

The external blame assessment is also distinct from the rule activation logic 422. The rule evaluation logic selectively activates rules applicable to the scenario. For example, the safe distance rule may be deactivated for any agent that is more than a certain distance behind the ego vehicle. The motivation for deactivating the safe distance rule in this situation might be that maintaining a safe distance is the responsibility of the other agent (not the ego vehicle) in this situation.

However, the external blame assessment logic 702 applies to activated rules, and operates to determine whether the ego agent or the other agent was the cause of the failure on the active rule.

To this end, an acceptable failure model 700 is defined for a given scenario and provided as a second input to the test oracle 252. The functionality of the rule editor 400 is extended for defining acceptable failure models. The focus of the following description, and the acceptable failure model 700, is failures on active rules that are not explained or justified by the internal hierarchy of the rules applicable to a given scenario run, and which require investigation of the behaviour of another agent in the scenario.

The described examples introduce at least three categories of result: “pass” and, in addition, two distinct categories or classes of “failure”- “acceptable failure” that is the fault of the other agent according to the acceptable failure model 700, and an “unacceptable failure” that is not the fault of the other agent according to the acceptable failure mode 700. Note the term “unacceptable” in this context refers specifically to the outcome against the acceptable failure model 700; it does not exclude the possibility that the rule is justified in some other sense (e.g. according to the internal rule hierarchy).

An alternative would be to encode some implicit notion of acceptable failure in a pass/fail-type rule. For example, consider a basic “no collision” rule that is failed whenever an area of the ego agent 602 intersects an area of the other agent 604, and passed otherwise. This rule could be extended to attach further conditions for failure dependent on the behaviour of the other agent 604. For example, the rule could instead be formulated as “fail whenever an area of the ego agent 602 intersects an area of the other agent 604 (collision event), unless a cut in action has been performed by the other agent less than T seconds before the collision event”. However, there are two problems with this approach. Firstly, it could result in a pass on the no collision rule, even when a collision takes place. That is a highly misleading characterization of the scenario run that could have critical implication in the context of safety testing.

An efficient two-stage implementation of acceptable failure is described. The rules 254 are formulated as pass/fail-type rules, and the first stage evaluates each applicable rule to compute pass/fail results at each time instant at which that rule is active, to determine a pass/fail result. The first stage is independent of the acceptable failure model 700. Second stage processing is only performed in response to a failure on the rule, in order to assess the behaviour of the other agent against the acceptable failure model 700 (blame analysis). This may be performed for all failures, or only certain failures - e.g. only failures on a specific rule or rule and/or failures that are not justified by the internal rule hierarchy.

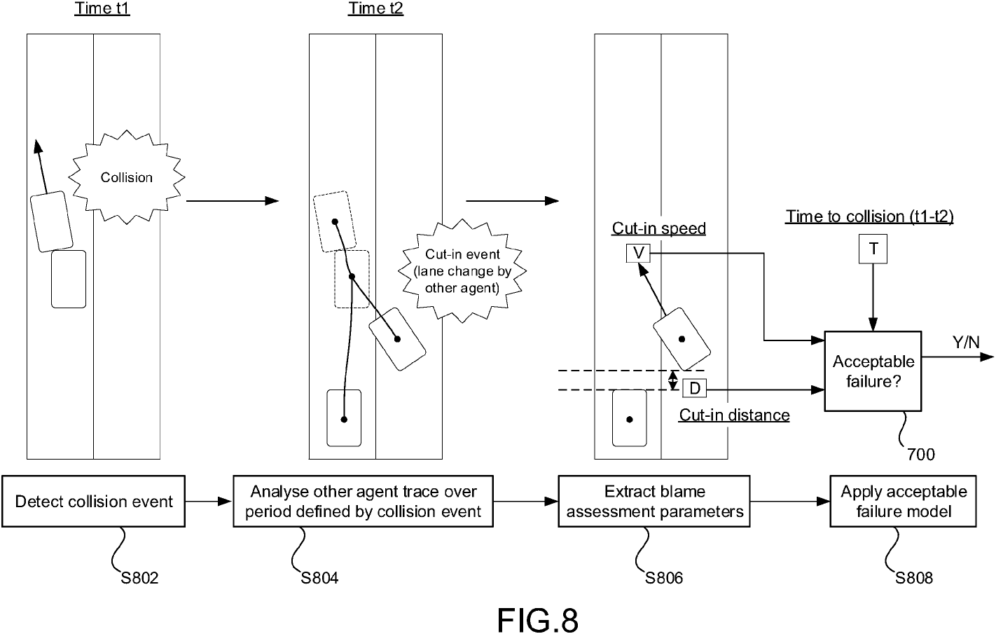

FIG. 8 shows a schematic flow chart for the second stage processing, together with a high-level visual representation of the processing performed at each step. The example of FIG. 8 considers a blame analysis instigated by the collision event in the scenario run of FIG. 6A, but the description applies more generally to other types of rule failure.

At step S802 a collision event is detected in a given scenario run, as a failure on some top-level “no collision” rule evaluated pairwise between the ego agent 602 and the other agent 604. The collision event is determined to occur at time t2 of the scenario run.

At step S804, in response to the detected collision event, the trace of the other agent 604 is analysed over a period of time before and/or after a timing of the collision event. In the present example, the trace of the other agent 604 is used to locate an earlier cut-in event at time t1 occurring within the time period under consideration. The cut-in event is defined at the point at which the other agent 604 crossed from the adjacent lane 614 into the ego lane 612.

A partial trace 704 of the other agent 604 between time t1 and time t2 is shown.

At step 806, the partial agent trace 704 is used to extract one or more blame assessment parameters. The blame assessment parameters are the parameter(s) required to evaluate the acceptable failure model 700 applicable to the scenario.

At step S808, the acceptable failure model 700 is applied to the extracted blame assessment parameters. That is to say, a rules-based evaluation of the blame assessment parameter(s) is performed according to the rule(s) of the acceptable failure model 700, in order to class the failure as acceptable or unacceptable in the above sense.

In the depicted cut-in scenario, one such parameter could be time-to-collision, t = t2 - t1, i.e. the time interval between the cut in event and the rule failure. For example, a simple blame assessment rule could be defined as follows:
“a collision is acceptable in a cut-in scenario if the other agent crosses the lane boundary of the ego lane with a time to collision of less than T”
where T is some predefined threshold (e.g. 2 seconds).

Other examples of potentially important parameters in a cut-in scenario are the speed, v, of the other agent 604 at the time t1 of the cut-in event, and cut-in distance, d, between the ego agent 602 and the other agent 604.

In the cut-in example, an overriding requirement of this particular blame assessment rule is that a cut-in event has occurred before the rule failure under investigation. This requirement could be evaluated by checking for the existence of a cut in event in the time period between time t1-T and time t1. In this case, a requirement for ascribing blame to the other agent is the existence of a cut-in event in that period.

Cut-in distance, d, is an example of a blame assessment parameter that also requires the cut-in event at time t1 to be identified. A partial trace 702 of the ego agent 602 is depicted in the visual representation of step S804, and the cut-in distance d is defined in this example as the lateral distance between a front bumper of the ego agent 602 and a rear bumper of the other agent 604.

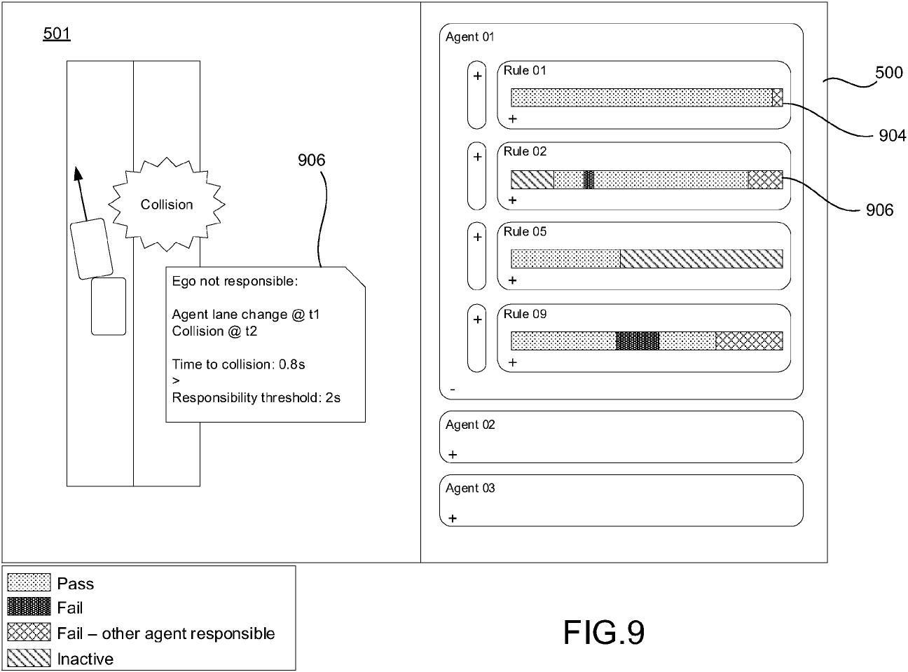

FIG. 9 shows an example of an extended GUI, to incorporate the results of a blame assessment analysis. Different colours (denoted by shading) are used to represent pass, acceptable failure and unacceptable failure. Over the duration of the depicted run, intervals of failure can be seen in the timelines for “Rule 01” and “Rule 02”. For example, Rule 01 could be the “no collision” rule and Rule 02 could be the “safe distance” rule. A blame analysis has been performed in relation to each interval of failure. First and second failure intervals 904 and 906, on Rule 01 and Rule 02 respectively, occur towards the end of the scenario when the cut-in and subsequent collision event occur. Those intervals 904, 906 have been visually marked as acceptable, whereas a third interval of failure 908 has been visually marked as unacceptable.

The visual representation 501 of the scenario run relates to the time t1 of the collision event. Details 906 of the blame analysis pertaining to time t1 are also displayed. For example, the details 906 may be displayed in response to the user selecting the corresponding interval 904 of the timeline of Rule 01 and/or navigating to time t1 in the visualization 501. Regarding the latter, a suitable GUI element, such as a slider 912 may be proved for this purpose.

FIG. 9A shows the visual representation 501 at an earlier time, with details 912 of the unacceptable failure interval 908 on Rule 02 obtained in the blame assessment analysis. This failure occurs before the cut-in by the other agent 604, and is therefore not explained by it. According to the acceptable failure model 700, the fault lies with the ego agent 602, and requires further investigation of the stack 100 under testing.

Whilst the above examples consider a collision event, the techniques can be applied more generally to other types of failure event. A failure event could be a failure result on a particular rule, but could also be a particular combination of failure results on a single rule or multiple rules. Having identified a failure event, a blame assessment analysis can be instigated and conveyed in a similar manner.

Note that the blame assessment parameter(s) are extracted parameters; a scenario parametrization must actually be run in order to extract the blame assessment parameter(s). A simpler form of acceptable failure model may be defined on the underlying scenario parameter(s) themselves, which does not require a given scenario parameterization to be run in order to determine whether or not failure would be acceptable.

An acceptable failure model could be “hard coded” by an expert, or it may be data-driven. For example, the acceptable failure model could be defined in terms of statistic(s) (statistical measure(s)) extracted from a driving scenario (or scenario parametrization), where failure on a particular (combinations of) statistic(s) is deemed acceptable based on corresponding statistics derived from real-world driving data. Examples of such statistics include number of frequency of events or of certain types of agent etc.

### Unacceptable Failure Search

Summarizing the above, one desirable aim in the context of AV testing is to find the most challenging scenarios. On the other hand, failure is only “interesting” on a certain subset of those scenarios. For example, collision outcomes are far more useful on driving scenarios on which a reasonable human driver should have passed. Therefore, a more useful aim is to find the most challenging scenarios, but subject to the constraint that failure on such scenarios is unacceptable in the above sense.

This can be formulated as a constrained optimization problem, where the aim is find some scenario parameterization (value or combination of values of the scenario parameter(s)) to maximize the extent of failure on a given metric(s), but subject to the constraint that failure on that parameterization is unacceptable according to the acceptable failure model 700.

Examples of constrained optimization methods that can be used in this context include branch-and-bound, Russian doll search, etc. The acceptable failure constraint can be encoded as one or more hard and/or soft constrains on the constrained optimization of the numerical performance metric.

A gradient-based optimization, such as projected gradient descent (or ascent) could be used, with the method of FIG. 6 modified accordingly.

For example, the method might involve some “step” in scenario space at each iteration (change in scenario parameterization), that is informed by earlier iteration(s). The acceptable failure model can then be used to determine whether or not (i) the stack 100 fails on the new scenario and (ii) whether or not that failure is acceptable (by applying the acceptable failure model). Depending on the implementation, it may be necessary to do only one of (i) and (ii) (for example, if the acceptable failure model is defined on the scenario parameters directly, it could be applied first without running the scenario; alternatively, if the AV stack 100 is tested first, it may not be necessary to apply the acceptable failure model if the stack 100 passes). If the step has moved into an “excluded” region of the scenario space (in which failure is acceptable), subsequent iteration(s) can be adapted to try to explore non-excluded regions of the scenario space (in which failure is unacceptable).

One approach to simulation records real-world instances of AV failure (e.g., in the most extreme cases, requiring test driver intervention) and re-produces those scenarios in the simulator, but allows the scenario to be modified by varying the scenario parameters θ. The present techniques can be applied to simulations based on real-world scenarios.

Scenarios can be obtained for the purpose of simulation in various ways, including manual encoding. The system is also capable of extracting scenarios for the purpose of simulation from real-world runs, allowing real-world situations and variations thereof to be re-created in the simulator 202.

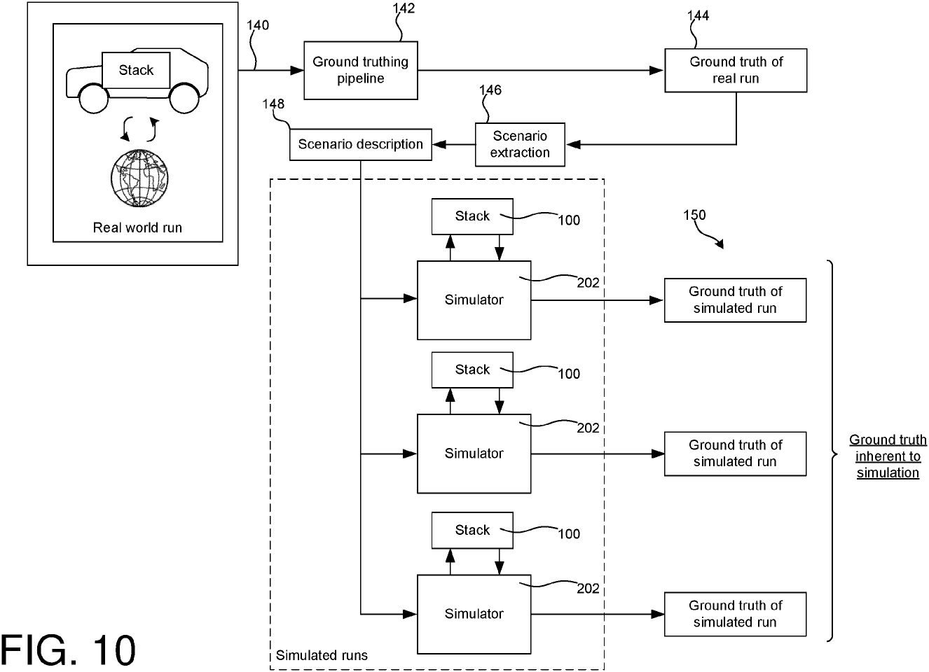

FIG. 10 shows a highly schematic block diagram of a scenario extraction pipeline. Data 140 of a real-world run is passed to a ‘ground-truthing’ pipeline 142 for the purpose of generating scenario ground truth. The run data 140 could comprise, for example, sensor data and/or perception outputs captured/generated on board one or more vehicles (which could be autonomous, human-driven or a combination thereof), and/or data captured from other sources such external sensors (CCTV etc.). The run data is processed within the ground truthing pipeline 142, in order to generate appropriate ground truth 144 (trace(s) and contextual data) for the real-world run. As discussed, the ground-truthing process could be based on manual annotation of the ‘raw’ run data 142, or the process could be entirely automated (e.g. using offline perception method(s)), or a combination of manual and automated ground truthing could be used. For example, 3D bounding boxes may be placed around vehicles and/or other agents captured in the run data 140, in order to determine spatial and motion states of their traces. A scenario extraction component 146 receives the scenario ground truth 144, and processes the scenario ground truth 144 to extract a more abstracted scenario description 148 that can be used for the purpose of simulation. The scenario description 148 is consumed by the simulator 202, allowing multiple simulated runs to be performed. The simulated runs are variations of the original real-world run, with the degree of possible variation determined by the extent of abstraction. Ground truth 150 is provided for each simulated run.

In the present off-board content, there is no requirement for the traces to be extracted in real-time (or, more precisely, no need for them to be extracted in a manner that would support real-time planning); rather, the traces are extracted “offline”. Examples of offline perception algorithms include non-real time and non-causal perception algorithms. Offline techniques contrast with “on-line” techniques that can feasibly be implemented within an AV stack 100 to facilitate real-time planning/decision making.

For example, it is possible to use non-real time processing, which cannot be performed on-line due to hardware or other practical constraints of an AV’s onboard computer system. For example, one or more non-real time perception algorithms can be applied to the real-world run data 140 to extract the traces. A non-real time perception algorithm could be an algorithm that it would not be feasible to run in real time because of the computation or memory resources it requires.

It is also possible to use “non-causal” perception algorithms in this context. A non-causal algorithm may or may not be capable of running in real-time at the point of execution, but in any event could not be implemented in an online context, because it requires knowledge of the future. For example, a perception algorithm that detects an agent state (e.g. location, pose, speed etc.) at a particular time instant based on subsequent data could not support real-time planning within the stack 100 in an on-line context, because it requires knowledge of the future (unless it was constrained to operate with a short look ahead window). For example, filtering with a backwards pass is a non-causal algorithm that can sometimes be run in real-time, but requires knowledge of the future.

The term “perception” generally refers to techniques for perceiving structure in the real-world data 140, such as 2D or 3D bounding box detection, location detection, pose detection, motion detection etc. For example, a trace may be extracted as a time-series of bounding boxes or other spatial states in 3D space or 2D space (e.g. in a birds-eye-view frame of reference), with associated motion information (e.g. speed, acceleration, jerk etc.).

Scoring scenarios systematically and numerically also has the benefit of being able to locate failure cases – which, in this context, would be scenarios for which one or more of the failure thresholds is breached – without requiring prior knowledge of which scenarios the stack 100 is likely to fail on. In this context, the present techniques have the benefit of being able to find scenarios on which the stack 100 fails unexpectedly, via systematic exploration of the scenario space.

References herein to components, functions, modules and the like, denote functional components of a computer system which may be implemented at the hardware level in various ways. A computer system comprises one or more computers that may be programmable or non-programmable. A computer comprises one or more processors which carry out the functionality of the aforementioned functional components. A processor can take the form of a general-purpose processor such as a CPU (Central Processing unit) or accelerator (e.g. GPU) etc. or more specialized form of hardware processor such as an FPGA (Field Programmable Gate Array) or ASIC (Application-Specific Integrated Circuit). That is, a processor may be programmable (e.g. an instruction-based general-purpose processor, FPGA etc.) or non-programmable (e.g. an ASIC). Such a computer system may be implemented in an onboard or offboard context.

1. A computer-implemented method of evaluating the performance of a full or partial autonomous vehicle (AV) stack in simulation, the method comprising:
applying an optimization algorithm to a numerical performance function defined over a scenario space, wherein the numerical performance function quantifies the extent of success or failure of the AV stack as a numerical score, and the optimization algorithm searches the scenario space for a driving scenario in which the extent of failure of the AV stack is substantially maximized;
wherein the optimization algorithm evaluates multiple driving scenarios in the search space over multiple iterations, by running a simulation of each driving scenario in a simulator, in order to provide perception inputs to the AV stack, and thereby generate at least one simulated agent trace and a simulated ego trace reflecting autonomous decisions taken in the AV stack in response to the simulated perception inputs, wherein later iterations of the multiple iterations are guided by the results of previous iterations of the multiple iterations, with the objective of finding the driving scenario for which the extent of failure of the AV stack is maximized.

2. The method of claim 1, wherein the later iterations are guided by the earlier iterations, in combination with a predetermined acceptable failure model, with the objective of finding a driving scenario for which (i) the extent of failure is maximized and (ii) failure is unacceptable according to the acceptable failure model, wherein any driving scenario having (iii) a greater extent of failure but (iv) on which failure is acceptable according to the acceptable failure model is excluded from the search.

3. The method of claim 2, wherein the acceptable failure model is applied to the simulated ego trace and the simulated agent trace of at least generated in at least one of the driving scenarios, in order to determine whether failure on that driving scenario is acceptable or unacceptable.

4. The method of claim 2, wherein the scenario space is defined by one or more scenario parameters, and the acceptable failure model excludes, from the search, predetermined values or combinations of values of the one or more scenario parameters.

5. The method of claim 2, wherein a constrained optimization method is used with the objective of finding a driving scenario fulfilling (i) and (ii), wherein (ii) is formulated as a set of one or more hard and/or soft constraints on the constrained optimization of (i).

6. The method of claim 2, wherein the acceptable failure model comprises one or more statistics derived from real-world driving data, which are compared with corresponding statistic(s) of a driving scenario, in order to determine whether or not failure on that driving scenario is acceptable.

7. The method of claim 2, wherein the acceptable failure model comprises one or more acceptable failure rules applied to one or more blame assessment parameters extracted from the simulated traces.

8. The method of claim 1, wherein the optimization algorithm is gradient-based, wherein each iteration computes a gradient of the performance function and the later iterations are guided by the gradients computed in the earlier iterations.

9. The method of claim 2, wherein a gradient-based constrained optimization method is used with the objective of finding a driving scenario fulfilling (i) and (ii), wherein (ii) is formulated as a set of one or more hard and/or soft constraints on the constrained optimization of (i), wherein each iteration computes a gradient of the performance function and the later iterations are guided by the gradients computed in the earlier iterations.

10. The method of claim 8, wherein the gradient of the performance function is estimated numerically in each iteration.

11. The method of claim 1, wherein each scenario in the scenario space is defined by a set of scenario description parameters to be inputted to the simulator, the simulated ego trace dependent on the scenario description parameters and the autonomous decisions taken in the AV stack.

12. The method of claim 1, wherein the performance function is an aggregation of multiple time-dependent numerical performance metrics used to evaluate the performance of the AV stack, the time-dependent numerical performance metrics selected in dependence on environmental information encoded in the description parameters or generated in the simulator.

13. The method of claim 1, wherein the numerical performance function is defined over a continuous numerical range.

14. The method of claim 1, wherein the numerical performance function is a discontinuous function over the whole of scenario space, but locally continuous over localized regions of the scenario space, wherein the method comprises checking that each of the multiple scenarios is within a common one of the localized regions.

15. The method of claim 1, wherein the numerical performance function is based on at least one of:
distance between an ego agent and another agent,
distance between an ego agent and an environmental element,
comfort assessed in terms of acceleration along the ego trace, or a first or higher order time derivative of acceleration,
progress.

16. A computer system comprising;
memory: and
one or more hardware processors programmed or otherwise configured to apply an optimization algorithm to a numerical performance function defined over a scenario space, wherein the numerical performance function quantifies the extent of success or failure of the AV stack as a numerical score, and the optimization algorithm searches the scenario space for a driving scenario in which the extent of failure of the AV stack is substantially maximized:
wherein the optimization algorithm evaluates multiple driving scenarios in the search space over multiple iterations, by running a simulation of each driving scenario in a simulator, in order to provide perception inputs to the AV stack, and thereby generate at least one simulated agent trace and a simulated ego trace reflecting autonomous decisions taken in the AV stack in response to the simulated perception inputs, wherein later iterations of the multiple iterations are guided by the results of previous iterations of the multiple iterations, with the objective of finding the driving scenario for which the extent of failure of the AV stack is maximized.

17. A non-transitory computer-readable storage medium comprising program instructions configured, upon execution by one or more hardware processors, to cause the one or more hardware processors to:
apply an optimization algorithm to a numerical performance function defined over a scenario space, wherein the numerical performance function quantifies the extent of success or failure of the AV stack as a numerical score, and the optimization algorithm searches the scenario space for a driving scenario in which the extent of failure of the AV stack is substantially maximized:
wherein the optimization algorithm evaluates multiple driving scenarios in the search space over multiple iterations, by running a simulation of each driving scenario in a simulator, in order to provide perception inputs to the AV stack, and thereby generate at least one simulated agent trace and a simulated ego trace reflecting autonomous decisions taken in the AV stack in response to the simulated perception inputs, wherein later iterations of the multiple iterations are guided by the results of previous iterations of the multiple iterations, with the objective of finding the driving scenario for which the extent of failure of the AV stack is maximized.

18. The computer system of claim 17, wherein the later iterations are guided by the earlier iterations, in combination with a predetermined acceptable failure model, with the objective of finding a driving scenario for which (i) the extent of failure is maximized and (ii) failure is unacceptable according to the acceptable failure model, wherein any driving scenario having (iii) a greater extent of failure but (iv) on which failure is acceptable according to the acceptable failure model is excluded from the search.

19. The computer system of claim 18, wherein the acceptable failure model is applied to the simulated ego trace and the simulated agent trace of at least generated in at least one of the driving scenarios, in order to determine whether failure on that driving scenario is acceptable or unacceptable.

20. The computer system of claim 18, wherein the scenario space is defined by one or more scenario parameters, and the acceptable failure model excludes, from the search, predetermined values or combinations of values of the one or more scenario parameters.
